(19) United States
(12) Patent Application Publication
(10) Pub. No.: US 2010/0190109 A1
(43) Pub. Date: Jul. 29, 2010

(54) ACID TRANSFER COMPOSITION, ACID TRANSFER FILM, AND PATTERN FORMING METHOD

(75) Inventor: Kouji NISHIKAWA, Tokyo (JP)

Correspondence Address: Ditthavong Mori & Steiner, P.C., 918 Prince Street, Alexandria, VA, 22314, US

(73) Assignee: JSR Corporation, Tokyo (JP)

(21) Appl. No.: 12/690,913

(22) Filed: Jan. 20, 2010

(30) Foreign Application Priority Data
Jan. 23, 2009 (JP) 2009-013649
Dec. 8, 2009 (JP) 2009-278940

(51) Int. Cl. G03F 7/004; G03F 7/20

(52) U.S. Cl. 430/283.1; 430/325

(57) ABSTRACT

The acid transfer composition of the invention comprises a radiation-sensitive acid generator, a polymer having a nitrogen-containing group and a ketone-based solvent. The composition may comprise further a sensitizer. The pattern forming method of the invention comprises a second resin film formation process in which the acid transfer composition is used to form a second resin film (acid transfer film) on a first resin film containing an acid-dissociable group-containing resin, but not containing a radiation-sensitive acid generator, an exposure process for exposing the second resin film to a light through a mask to generate an acid in the second resin film, an acid transfer process for transferring the acid generated in the second resin film to the first resin film, and a second resin film removing process.

### BACKGROUND OF THE INVENTION

1. Field of the Invention

The present invention relates to an acid transfer composition, an acid transfer film, and a pattern forming method. More specifically, the present invention relates to an acid transfer composition suitably used in technology in which a pattern is formed on a film containing no acid generators, an acid transfer film which is formed using the acid transfer composition, and a pattern forming method.

2. Description of Related Art

In the field of microfabrication represented by the manufacture of integrated circuit devices, a pattern forming method in which a radiation-sensitive resin composition comprising a resin having an acid-dissociable functional group and an acid generator is used has been conventionally known. According to this method, an acid is generated from the acid generator upon exposure, and a specific functional group is dissociated from the resin having an acid-dissociable functional group, whereby the resin becomes alkali-soluble.

In contrast, methods for patterning on a resin film containing no acid generators have been known (see JP-A 2004-85955, JP-A 2001-272402, WO 1990/015070, JP-T 2005-523232, and JP-A 2006-258806).

### SUMMARY OF THE INVENTION

The technology for patterning on a patterning target resin film containing no acid generators requires to uniformly diffuse an acid over the entire surface of the patterning target resin film, while selectively diffusing the acid to necessary areas of the patterning target resin film. However, an acid transfer film capable of diffusing an acid selectively with sufficient accuracy over the entire surface of the patterning target resin film on which a pattern is formed has not been known.

The present invention has been achieved in view of this situation and has an object of providing an acid transfer composition which can uniformly diffuse an acid over the entire surface of a patterning target resin film with sufficient accuracy and, as a result, which can produce a uniform acid transfer film capable of forming a pattern excellent in dimensional stability on the surface of the patterning target resin film, an acid transfer film which is formed using the acid transfer composition, and a pattern forming method that can form a pattern by a photolithographic process using the acid transfer film.

The present invention is as follows.

(1) An acid transfer composition comprising (A) a radiation-sensitive acid generator, (B) a polymer having a nitrogen-containing group, and (C) a ketone-based solvent.
(2) The acid transfer composition according to (1) above, wherein the polymer (B) comprises a polymer having a structural unit represented by the following general formula (1),

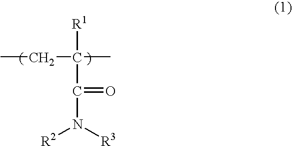

wherein R¹ is a hydrogen atom or a methyl group, and R² and R³ individually are a hydrogen atom, a linear or branched hydrocarbon group having 1 to 10 carbon atoms, or a cyclic hydrocarbon group having 3 to 10 carbon atoms, or R² and R³ may bond to form a 3 to 10 membered monocyclic hetero ring containing a nitrogen atom, an oxygen atom, a sulfur atom or a selenium atom.
(3) The acid transfer composition according to (1) or (2) above, wherein the ketone-based solvent is contained in an amount from 10 to 10,000 parts by weight based on 100 parts by weight of the polymer (B).
(4) The acid transfer composition according to any one of (1) to (3) above, wherein the polymer (B) has a structural unit represented by the following general formula (2),

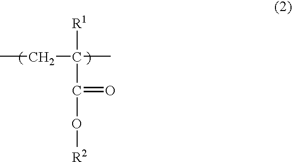

wherein R¹ is a hydrogen atom or a methyl group, and R² is a monovalent organic group.
(5) The acid transfer composition according to any one of (1) to (4) above, wherein the radiation-sensitive acid generator (A) is a compound having an imide sulfonate group.
(6) The acid transfer composition according to any one of (1) to (5) above, further comprising (E) sensitizer.
(7) The acid transfer composition according to (6) above, wherein the sensitizer (E) is a compound represented by the following general formula (20),

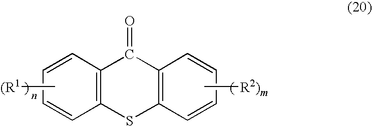

wherein R¹ and R² individually are an alkyl group or a halogen atom, and n and m individually an integer of 1 to 4.
(8) An acid transfer film which is formed using the acid transfer composition according to (1) to (7) above.
(9) A pattern forming method comprising sequentially (I) a second resin film formation process for forming a second resin film as an acid transfer film on a first resin film using the acid transfer composition according to any one of (1) to (7) above, the first resin film comprising an acid-dissociable group-containing resin, but not comprising a radiation-sensitive acid generator, (II) an exposure process for exposing the second resin film to a light through a mask to generate an acid in the second resin film, (III) an acid transfer process for transferring the acid generated in the second resin film to the first resin film, and (IV) a second resin film removing process for removing the second resin film.

According to the acid transfer composition of the present invention, a pattern can be formed on a patterning target resin film (that is a resin film on which a pattern is formed) using a photolithographic process even if the patterning target resin film does not contain an acid generator.

In the case where the polymer (B) has the structural unit represented by the general formula (1), the present composition contains both of the polymer having the structural unit of the general formula (1) and a ketone-based solvent and the resulting acid transfer film exhibits not only more excellent acid diffusion over the entire surface of the patterning target resin film, but also superior acid transfer selectivity as compared with other acid transfer compositions. The acid generated in the acid transfer film formed using the acid transfer composition of the present invention particularly can suppress unnecessary diffusion of an acid in the crosswise direction within the patterning target resin film which is a transferring target, while ensuring uniform acid diffusion over the entire surface of the patterning target resin film. As a result, the resulting pattern has high dimensional stability and can faithfully reproduce the target line-and-space. A better pattern can thus be obtained.

In the case where the content of the ketone-based solvent is in the range from 10 to 1,000 parts by weight based on 100 parts by weight of the polymer (B), more uniform acid diffusion can be obtained over the entire surface of the patterning target resin film.

In the case where the polymer (B) has a structural unit represented by the general formula (2), the transfer efficiency of the generated acid can be easily controlled.

In the case where the radiation-sensitive acid generator (A) contains an imide sulfonate-based group, the resulting acid transfer film can exhibit more excellent acid transfer selectivity and a particularly good pattern can be formed than the case in which an acid transfer composition not containing an acid generator having an imide sulfonate-based group is used.

In the case where the acid transfer composition of the present invention contains a sensitizer (E), sensitivity to exposure can be promoted.

In the case where the sensitizer (E) is a compound represented by the general formula (20), particularly excellent sensitivity can be obtained in a combination of the radiation-sensitive acid generator (A), the polymer (B), and the ketone-based solvent (C).

According to the acid transfer film of the present invention, a pattern can be formed on a patterning target resin film using a general photolithographic process even if the patterning target resin film does not contain an acid generator. In particular, since the acid transfer film is formed using the composition containing both of the polymer (B) having the structural unit represented by the general formula (1) and a ketone-based solvent (C), the resulting acid transfer film exhibits not only more excellent acid diffusion over the entire surface of the patterning target resin film, but also superior acid transfer selectivity as compared with other acid transfer compositions. The acid generated in the acid transfer film of the present invention particularly can suppress unnecessary diffusion of an acid in the crosswise direction within the patterning target resin film which is the transferring target, while ensuring uniform acid diffusion over the entire surface of the patterning target resin film. As a result, the resulting pattern has high dimensional stability and can faithfully reproduce the target line-and-space over the entire surface.

According to the pattern forming method of the present invention, a pattern can be formed on a patterning target resin film (i.e., the first resin film) using a general photolithographic process even if the patterning target resin film does not contain an acid generator. In particular, since the second resin film (acid transfer film) is formed using the composition containing both of the polymer (B) having the structural unit represented by the general formula (1) and a ketone-based solvent (C), the resulting acid transfer film exhibits not only more excellent acid diffusion over the entire surface of the patterning target resin film, but also superior acid transfer selectivity as compared with other acid transfer compositions. The acid generated in the second resin film particularly can suppress unnecessary diffusion of an acid in the crosswise direction within the patterning target resin film which is the transferring target, while ensuring uniform acid diffusion over the entire surface of the patterning target resin film. As a result, the resulting pattern has high dimensional stability and can faithfully reproduce the target line-and-space over the entire surface.

### BRIEF DESCRIPTION OF THE DRAWINGS

FIG. 1 is a schematic view for illustrating the pattern forming method of the present invention.

### DETAILED DESCRIPTION OF THE INVENTION

Hereinafter, the present invention is described in detail. In the specification, “(meth)acryl” means acryl and methacryl, and “(meth)acrylate” means acrylate and methacrylate.

### 1. Acid Transfer Composition

The acid transfer composition of the present invention is characterized by comprising (A) a radiation-sensitive acid generator, (B) a polymer having a nitrogen-containing group, and (C) a ketone-based solvent.

The acid transfer composition of the present invention is capable of forming a film as described later. When the resulting film is subjected to exposure, an acid can be generated selectively in a desired area of the resulting film so that a pattern consisting of an area in which an acid has been generated and an area in which no acid has been generated can be formed. The acid generated in the film formed using the acid transfer composition of the present invention can be transferred to an adjoining layer. That is to say, the acid transfer composition of the present invention is a composition used to prepare an acid transfer film. In addition, the resulting acid transfer film is laminated with another film to which the acid generated therein by exposure is then transferred.

### 1-1. Radiation-Sensitive Acid Generator (A)

The type of the radiation for leading radiation-sensitivity is not particularly limited. Example thereof include ultraviolet rays, deep ultraviolet rays such as KrF excimer laser beams, ArF excimer laser beams and F₂ excimer laser beams, X-rays, electron beams, γ-rays, molecular beams, ion beams, and the like and these can be appropriately used.

Examples of the acid generator (A) include: (A1) a compound having an imide sulfonate group (imide sulfonate-based radiation-sensitive acid generator); (A2) a compound having an oxime sulfonate group (oxime sulfonate-based radiation-sensitive acid generator); (A3) an onium salt compound (including a thiophenium salt compound); (A4) a halogen-containing compound; (A5) a diazoketone compound; (A6) a sulfone compound; (A7) a sulfonic acid compound; (A8) a sulfonimide compound; (A9) a diazomethane compound; and the like. The acid generator (A) may be used singly or in combination of two or more types thereof. Among these, an imide sulfonate-based radiation-sensitive acid generator is preferable. When the composition of the present invention contains the imide sulfonate-based radiation-sensitive acid generator, particularly excellent acid transfer selectivity can be obtained.

### 1-1-1. Imide Sulfonate-Based Radiation-Sensitive Acid Generator (A1)

The imide sulfonate-based radiation-sensitive acid generator (A1) is a compound represented by the following general formula (3).

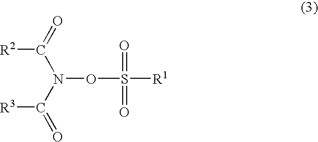

(In the formula, R¹ is an alkyl group having 1 to 14 carbon atoms, an aryl group having 6 to 20 carbon atoms or an alicyclic group having 4 to 20 carbon atoms, and R² and R³ bond together to form a cyclic structure or are individually an alkyl group having 1 to 14 carbon atoms, an aryl group having 6 to 20 carbon atoms, or an alicyclic group having 4 to 20 carbon atoms.)

In the general formula (3), R² and R³ bond together to form a cyclic structure or may be individually an alkyl group having 1 to 14 carbon atoms, an aryl group having 6 to 20 carbon atoms, or an alicyclic group having 4 to 20 carbon atoms. In the present invention, R² and R³ preferably bond together to form a cyclic structure.

Additionally, R² and R³ preferably bond together to form an aromatic ring structure having 6 to 20 carbon atoms. Particularly, R² and R³ preferably bond together to form a polycyclic aromatic ring structure having 10 to 14 carbon atoms. It is particularly preferable that the imide sulfonate-based radiation-sensitive acid generator (A1) is a compound represented by the following general formula (4), in which R² and R³ bond together to form a naphthalene ring structure.

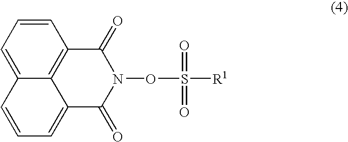

(In the formula, R¹ is an alkyl group having 1 to 14 carbon atoms, an aryl group having 6 to 20 carbon atoms, or an alicyclic group having 4 to 20 carbon atoms.)

R¹ in the general formula (4) is the same as R¹ in the general formula (3) and may be an alkyl group having 1 to 14 carbon atoms, an aryl group having 6 to 20 carbon atoms, an alicyclic group having 4 to 20 carbon atoms, and the like.

The alkyl group having 1 to 14 carbon atoms represented by R¹ in the above-mentioned general formula (4) may be either a linear alkyl group or a branched alkyl group. Examples of the alkyl group include methyl group, ethyl group, n-propyl group, isopropyl group, n-butyl group, 2-methyl propyl group, n-pentyl group, n-hexyl group, n-heptyl group, n-octyl group, n-nonyl group, n-decyl group, n-undecyl group, n-dodecyl group, n-tridecyl group, n-tetradecyl group and the like.

The alkyl group may have one or more substituents. Examples of the substituent include a hydroxyl group, a carboxyl group, an oxo group (═O), a cyano group, a halogen atom such as fluorine atom, chlorine atom and bromine atom, an alkoxy group such as methoxy group, ethoxy group, propoxy group and butoxy group, an alkyloxycarbonyl group and the like. When the alkyl group has two or more substituents, these substituents may be either the same or different.

The imide sulfonate-based radiation-sensitive acid generator (A) in which R¹ in the general formula (4) is a methyl group is a compound represented by the following formula (5).

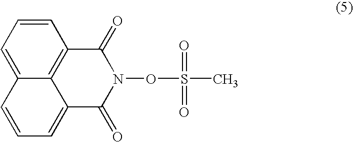

The aryl group having 6 to 20 carbon atoms for R¹ in the general formula (4) may or may not have one or more substituents. Examples of the aryl group include a phenyl group, a naphthyl group, an anthryl group, a phenanthryl group, a tolyl group, a p-methoxyphenyl group, a mesityl group, an o-cumenyl group, a xylyl group, and the like.

The imide sulfonate-based radiation-sensitive acid generator (A) in which R¹ in the general formula (4) is a tolyl group (particularly a p-tolyl group) is a compound represented by the following formula (6).

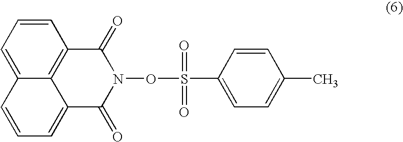

The alicyclic group having 4 to 20 carbon atoms for R¹ in the general formula (4) may or may not have an unsaturated bond and may or may not have a substituent. Examples of the substituent include the above-mentioned substituents in the alkyl group having 1 to 14 carbon atoms, a methyl group, an ethyl group, and the like.

The alicyclic structural part in the alicyclic group may be either a monocyclic ring or a polycyclic ring. Additionally, in the case of the polycyclic ring, the ring may be either a condensed ring or a non-condensed ring. Further, the alicyclic structural part may be either bridged or nonbridged.

Examples of the alicyclic group include an alicyclic group having a norbornane skeleton, an Acyclic group having a norbornene skeleton, an alicyclic group having a tricyclodecane skeleton, an alicyclic group having a tetracyclododecane skeleton, an alicyclic group having an adamantane skeleton, a cyclohexyl group, a cycloheptyl group, a cyclooctyl group, a cyclodecanyl group, a cyclododecanyl group and the like.

Among these, an alicyclic group having a norbornane skeleton and an alicyclic group having a camphor skeleton are preferable.

The imide sulfonate-based radiation-sensitive acid generator (A) in which R¹ in the general formula (4) is an alicyclic group having a camphor skeleton is a compound represented by the following formula (7).

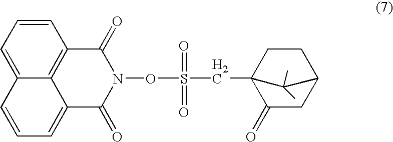

### 1-1-2. Oxime Sulfonate-Based Radiation-Sensitive Acid Generator (A2)

The oxime sulfonate-based radiation-sensitive acid generator (A2) is a compound having at least one group represented by the following general formula (8).

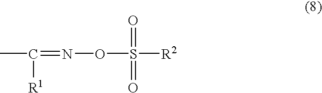

### (In the Formula, R¹ and R² are Individually Monovalent Organic Groups.)

R¹ and R² in the general formula (8) may have an atom other than a carbon atom. Examples of the atom other than a carbon atom include a hydrogen atom, an oxygen atom, a nitrogen atom, a sulfur atom, a halogen atom such as fluorine atom and chlorine atom, a selenium atom, and the like.

The oxime sulfonate radiation-sensitive acid generator (A2) may be a compound having two or more groups represented by the general formula (8), however, it is preferably a compound having only one group represented by the general formula (8). Additionally, the acid generator (A2) is preferably a compound that has a monovalent aromatic group bonding to the bonding hand of the group represented by the general formula (8) and has a cyano group, an alkyl group or a haloalkyl group for R¹ in the group represented by the general formula (8), that is, a compound represented by the following general formula (9).

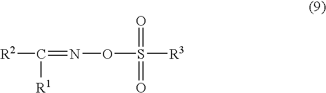

(In the formula, R¹ is a cyano group, an alkyl group or a haloalkyl group, R² is a monovalent aromatic group, and R³ is a monovalent organic group.)

In the above-mentioned general formula (9), R¹ is a cyano group, an alkyl group or a haloalkyl group. The alkyl group is preferably an alkyl group having no substituent and may be either a linear alkyl group or a branched alkyl group. The number of carbon atoms is not particularly limited and is preferably in the range from 1 to 14. Examples of the alkyl group include methyl group, ethyl group, n-propyl group, isopropyl group, n-butyl group, 2-methyl propyl group, n-pentyl group, n-hexyl group, n-heptyl group, n-octyl group, n-nonyl group, n-decyl group, n-undecyl group, n-dodecyl group, n-tridecyl group, n-tetradecyl group and the like.

The preferred R¹ in the above-mentioned general formula (9) is a cyano group.

There are no particular limitations to the number of carbon atoms in the monovalent aromatic group represented for R² in the general formula (9). The number thereof is preferably in the range from 6 to 20. Additionally, the aromatic ring constituting the monovalent aromatic group may be a benzene ring, a naphthalene ring, or an aromatic ring having a larger number of condensed rings. Specific examples of the monovalent aromatic group include a phenyl group, a naphthyl group, an anthryl group, a phenanthryl group and a monovalent aromatic group in which at least one hydrogen atoms in these groups are substituted with a functional group. Among these, the aromatic ring constituting the monovalent aromatic group is preferably a benzene ring.

The monovalent aromatic group represented for R² in the general formula (9) may have one or more substituents. Examples of the substituent include an alkoxy group such as methoxy group, ethoxy group, propoxy group and butoxy group, an alkyl group having 1 to 5 carbon atoms, a hydroxyl group, a carboxyl group, an oxo group (═O), a cyano group, a halogen atom such as fluorine atom, chlorine atom and bromine atom, an alkyloxycarbonyl group, and the like. When the aromatic group has two or more substituents, these substituents may be either the same or different. Examples of the monovalent aromatic group for R² in the general formula (3) include p-methoxyphenyl group, m-methoxyphenyl group, o-methoxyphenyl group, p-tolyl group, m-tolyl group, o-tolyl group, 2,4,6-mesityl group, p-cumenyl group, m-cumenyl group, o-cumenyl group, 2,4-xylyl group, 3,5-xylyl group, benzyl group and the like.

Of the above substituents, an alkoxy group is preferable, an alkoxy group having 1 to 4 carbon atoms is more preferable, and methoxy group is particularly preferable. Therefore, a methoxyphenyl group is preferable as the monovalent aromatic group for R² in the general formula (9). In the case where R² in the general formula (9) is an alkoxyphenyl group, the alkoxyphenyl group may be p-alkoxyphenyl group, m-alkoxyphenyl group or o-alkoxyphenyl group. Among these, p-alkoxyphenyl group is preferable and p-methoxyphenyl group is particularly preferred.

Furthermore, R³ in the general formula (9) is not particularly limited so long as it is a monovalent organic group. The preferable R³ is an alkyl group having 1 to 14 carbon atoms, an aryl group having 6 to 20 carbon atoms, an alicyclic hydrocarbon group having 4 to 20 carbon atoms, an organic group in which at least one hydrogen atom in these groups are substituted with an alkyl group having 1 to 4 carbon atoms, an aryl group having 6 to 20 carbon atoms, or a polar group other than a hydrocarbon group.

Therefore, the oxime sulfonate-based radiation-sensitive acid generator (A2) is preferably a compound in which R¹ in the general formula (9) is a cyano group and R² is a p-methoxyphenyl group, that is, a compound represented by the following general formula (10).

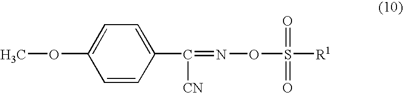

(In the formula, R¹ is an alkyl group having 1 to 14 carbon atoms, an aryl group having 6 to 20 carbon atoms, an alicyclic hydrocarbon group having 4 to 20 carbon atoms, an organic group in which at least one hydrogen atom in these groups are substituted with an alkyl group having 1 to 4 carbon atoms, an aryl group having 6 to 20 carbon atoms, or a polar group other than a hydrocarbon group.)

The alkyl group having 1 to 14 carbon atoms for R¹ in the general formula (10) may have a substituent, and the alkyl group having no substituent is more preferable. As the substituent, those in the description for R² in the general formula (9) can be given. The alkyl group may be either a linear alkyl group or a branched alkyl group. Among these, a linear alkyl group is more preferable. Examples of the alkyl group having 1 to 14 carbon atoms include methyl group, ethyl group, n-propyl group, isopropyl group, n-butyl group, 2-methyl propyl group, n-pentyl group, n-hexyl group, n-heptyl group, n-octyl group, n-nonyl group, n-decyl group, n-undecyl group, n-dodecyl group, n-tridecyl group, n-tetradecyl group and the like. Among these, an alkyl group having 3 to 12 carbon atoms is preferable, an alkyl group having 4 to 10 carbon atoms is more preferable, n-octyl group, n-nonyl group and n-decyl group are further preferable, and n-octyl group is particularly preferred.

The oxime sulfonate-based radiation-sensitive acid generator (A2) in which R¹ in the general formula (10) is an n-octyl group is represented by the following formula (11).

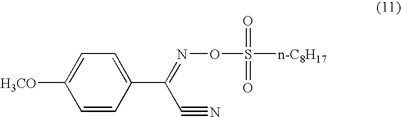

The aryl group having 6 to 20 carbon atoms for R¹ in the general formula (10) may have one or more substituents. As the substituent, those in the description for R² in the general formula (9) can be given. Specific examples of the substituent include an alkyl group having 1 to 5 carbon atoms, a hydroxyl group, a carboxyl group, an oxo group (═O), an alkoxy group such as methoxy group, ethoxy group, propoxy group and butoxy group, an alkyloxycarbonyl group, a halogen atom such as fluorine atom, chlorine atom and bromine atom, a cyano group, and the like. When the aryl group has two or more substituents, these substituents may be either the same or different. Examples of the aryl group having 6 to 20 carbon atoms for R¹ in the general formula (10) include p-tolyl group, m-tolyl group, o-tolyl group, 2,4-xylyl group, 3,5-xylyl group, 2,4,6-mesityl group, benzyl group, p-cumenyl group, m-cumenyl group, o-cumenyl group, p-methoxyphenyl group, m-methoxyphenyl group, o-methoxyphenyl group, and the like. Among these, p-tolyl group, p-methoxyphenyl group and p-cumenyl group are preferable and p-tolyl group is particularly preferred.

The oxime sulfonate-based radiation-sensitive acid generator (A2) in which R¹ in the general formula (10) is a p-tolyl group is represented by the following formula (12).

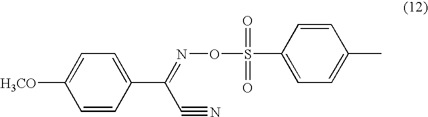

The alicyclic group having 4 to 20 carbon atoms for R¹ in the general formula (10) may or may not have an unsaturated bond and may or may not have a substituent. Examples of the substituent include the above-mentioned substituents in the alkyl group having 1 to 14 carbon atoms, a methyl group, an ethyl group, and the like.

The alicyclic structural part in the alicyclic group may be either a monocyclic ring or a polycyclic ring. Additionally, in the case of the polycyclic ring, the ring may be either a condensed ring or a non-condensed ring. Further, the alicyclic structural part may be either bridged or nonbridged.

Examples of the alicyclic group include an alicyclic group having a norbornane skeleton, an alicyclic group having a norbornene skeleton, an alicyclic group having a tricyclodecane skeleton, an alicyclic group having a tetracyclododecane skeleton, an alicyclic group having an adamantane skeleton, a cyclohexyl group, a cycloheptyl group, a cyclooctyl group, a cyclodecanyl group, a cyclododecanyl group and the like.

Among these, an alicyclic group having a norbornane skeleton and an alicyclic group having a camphor skeleton are preferable.

The oxime sulfonate-based radiation-sensitive acid generator (A2) in which R¹ in the general formula (10) is an alicyclic group having a camphor skeleton is a compound represented by the following formula (13).

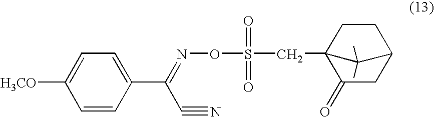

### 1-1-3. Onium Salt Compound (A3)

Examples of the onium salt compound (A3) include a thiophenium salt compound, an iodonium salt compound, a sulfonium salt compound, a phosphonium salt compound, a diazonium salt compound, a pyridinium salt compound and the like.

Examples of the thiophenium salt compound include a 4,7-di-n-butoxynaphthyltetrahydrothiophenium salt compound, a 1-(4-n-butoxynaphthalen-1-yl)tetrahydrothiophenium salt compound, a 1-(6-n-butoxynaphthalen-2-yl)tetrahydrothiophenium salt compound, a 1-(3,5-dimethyl-4-hydroxyphenyl)tetrahydrothiophenium salt compound and the like.

Examples of the 4,7-di-n-butoxynaphthyltetrahydrothiophenium salt compound include 4,7-di-n-butoxynaphthyltetrahydrothiophenium trifluoromethanesulfonate and the like.

Examples of the 1-(4-n-butoxynaphthalen-1-yl)tetrahydrothiophenium salt compound include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulfonate and the like.

Examples of the 1-(6-n-butoxynaphthalen-2-yl)tetrahydrothiophenium salt compound include 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium camphorsulfonate and the like.

Examples of the 1-(3,5-dimethyl-4-hydroxyphenyl)tetrahydrothiophenium salt compound include 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium camphorsulfonate and the like.

Examples of the iodonium salt compound include a bis(4-t-butylphenyl)iodonium salt compound, a diphenyliodonium salt compound and the like.

Examples of the bis(4-t-butylphenyl)iodonium salt compound include bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, bis(4-t-butylphenyl)iodonium camphorsulfonate and the like.

Examples of the diphenyliodonium salt compound include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, diphenyliodonium p-toluenesulfonate, diphenyliodonium hexafluoroantimonate, diphenyliodonium hexafluorophosphate, diphenyliodonium tetrafluoroborate and the like.

Examples of sulfonium salt compound include a triphenylsulfonium salt compound, a 4-t-butylphenyldiphenylsulfonium salt compound, a 4-cyclohexylphenyldiphenylsulfonium salt compound, a 4-methanesulfonylphenyldiphenylsulfonium salt compound and the like.

Examples of the triphenylsulfonium salt compound include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, triphenylsulfonium hexafluorophosphate and the like.

Examples of the 4-t-butylphenyldiphenylsulfonium salt compound include 4-t-butylphenyldiphenylsulfonium trifluoromethanesulfonate, 4-t-butylphenyldiphenylsulfonium perfluoro-n-octanesulfonate, 4-t-butylphenyldiphenylsulfonium pyrenesulfonate, 4-t-butylphenyldiphenylsulfonium n-dodecylbenzenesulfonate, 4-t-butylphenyldiphenylsulfonium p-toluenesulfonate, 4-t-butylphenyldiphenylsulfonium benzenesulfonate and the like.

Examples of the 4-cyclohexylphenyldiphenylsulfonium salt compound include 4-cyclohexylphenyldiphenylsulfonium trifluoromethane sulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1,1,2,2-tetrafluoroethanesulfonate, 4-cyclohexylphenyldiphenylsulfonium camphorsulfonate and the like.

Examples of the 4-methane sulfonylphenyldiphenylsulfonium salt compound include 4-methanesulfonylphenyldiphenylsulfonium trifluoromethane sulfonate, 4-methanesulfonylphenyldiphenylsulfonium nonafluoro-n-butanesulfonate, 4-methanesulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, 4-methanesulfonylphenyldiphenylsulfonium camphorsulfonate and the like.

### 1-1-4. Halogen-Containing Compound (A4)

Examples of the halogen-containing compound (A4) include a haloalkyl group-containing hydrocarbon compound, a haloalkyl group-containing heterocyclic compound and the like. Specific example thereof includes 1,10-dibromo-n-decane, 1,1-bis(4-chlorophenyl)-2,2,2-trichloroethane, a (trichloromethyl)-s-triazine derivatives such as phenyl-bis(trichloromethyl)-s-triazine, 4-methoxyphenyl-bis(trichloromethyl)-s-triazine, styryl-bis(trichloromethyl)-s-triazine and naphthyl-bis(trichloromethyl)-s-triazine, and the like.

### 1-1-5. Diazoketone Compound (A5)

Examples of the diazoketone compound (A5) include a 1,3-diketo-2-diazo compound, a diazobenzoquinone compound, a diazonaphthoquinone compound and the like. Specific example thereof includes a 1,2-naphthoquinonediazido-4-sulfonic acid esters of phenols, a 1,2-naphthoquinonediazido-5-sulfonic acid esters of phenols, and the like.

### 1-1-6. Sulfone Compound (A6)

Examples of the sulfone compound (A6) include a β-ketosulfone, a β-sulfonylsulfone, an α-diazo compound of these compounds and the like. Specific example thereof includes 4-tolylphenacyl sulfone, mesitylphenacyl sulfone, bis(phenylsulfonyl)methane and the like.

### 1-1-7. Sulfonic Acid Compound (A7)

Examples of the sulfonic acid compound (A7) include an alkyl sulfonate, a haloalkyl sulfonate, an aryl sulfonate, an imino sulfonate and the like. Specific example thereof includes benzointocylate, pyrogallol tristrifluoromethanesulfonate, o-nitrobenzyl trifluoromethanesulfonate, o-nitrobenzyl p-toluenesulfonate and the like.

### 1-1-8. Sulfonimide Compound (A8)

Examples of the sulfonimide compound (A8) include N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hept-5-ene-2,3-dicarboximide, N-(trifluoromethylsulfonyloxy)-7-oxabicyclo[2.2.1]hept-5-ene-2,3-dicarboximide, N-(trifluoromethylsulfonyloxy)-5,6-oxy-bicyclo[2.2.1]heptane-2,3-dicarboxyimide, N-(trifluoromethylsulfonyloxy)naphthylimide, N-(4-methylphenylsulfonyloxy)succinimide, N-(4-methylphenylsulfonyloxy)phthalimide, N-(4-methylphenylsulfonyloxy)diphenylmaleimide, N-(4-methylphenylsulfonyloxy)bicyclo[2.2.1]hept-5-ene-2,3-dicarboxyimide, N-(4-methylphenylsulfonyloxy)-7-oxabicyclo[2.2.1]hept-5-ene-2,3-dicarboxyimide, N-(4-methylphenylsulfonyloxy)-5,6-oxy-bicyclo[2.2.1]heptane-2,3-dicarboxyimide, N-(4-methylphenylsulfonyloxy)naphthylimide, N-(2-trifluoromethylphenylsulfonyloxy)succinimide, N-(2-trifluoromethylphenylsulfonyloxy)phthalimide, N-(2-trifluoromethylphenylsulfonyloxy)diphenylmaleimide, N-(2-trifluoromethylphenylsulfonyloxy)bicyclo[2.2.1]hept-5-ene-2,3-dicarboxyimide, N-(2-trifluoromethylphenylsulfonyloxy)-7-oxabicyclo[2.2.1]hept-5-ene-2,3-dicarboxyimide, N-(2-trifluoromethylphenylsulfonyloxy)-5,6-oxy bicyclo[2.2.1]heptane-2,3-dicarboxyimide, N-(2-trifluoromethylphenylsulfonyloxy)naphthylimide, N-(4-fluorophenylsulfonyloxy)succinimide, N-(4-fluorophenylsulfonyloxy)-7-oxabicyclo[2.1.1]hepto-5-ene-2,3-dicarboxyimide, N-(4-fluorophenylsulfonyloxy)-5,6-oxybicyclo[2.2.1]heptane-2,3-dicarboxyimide, N-(4-fluorophenylsulfonyloxy)naphthylimide, N-(10-camphorsulfonyloxy)naphthylimide and the like.

### 1-1-9. Diazomethane Compound (A9)

Examples of the diazomethane compound (A9) include bis(trifluoromethylsulfonyl)diazomethane, bis(cyclohexylsulfonyl)diazomethane, bis(phenylsulfonyl)diazomethane, bis(p-toluenesulfonyl)diazomethane, methylsulfonyl-p-toluenesulfonyldiazomethane, cyclohexylsulfonyl-1,1-dimethylethylsulfonyl diazomethane, bis(1,1-dimethylethylsulfonyl)diazomethane, and the like.

The content of the acid generator (A) in the acid transfer composition of the present invention is not particularly limited and is usually in the range from 0.1 to 500 parts by weight, preferably from 0.3 to 300 parts by weight and more preferably from 1 to 250 parts by weight based on 100 parts by weight of the polymer (B) from the viewpoint of ensuring acid transferring capability as an acid transfer film.

### 1-2. Polymer (B)

The polymer (B) is a polymer having a nitrogen-containing group. Since the polymer (B) is contained in the acid transfer composition together with the radiation-sensitive acid generator (A), unnecessary diffusion of an acid generated in a layer obtained using the acid transfer composition (hereinafter, referred to as “acid transfer layer”, this layer may also be referred to as an “acid generator-containing layer”) can be prevented. The effect of preventing unnecessary diffusion of an acid generated in the acid transfer layer is hereinafter referred to also as “acid diffusion preventing effect”. Unintended acid diffusion and acid transfer in the acid transfer layer and to the underlayers can be prevented and the resolution of the resulting pattern can be promoted due to the acid diffusion preventing effect. By promoting the resolution, not only can a pattern be formed correctly and precisely, but also the rate of accumulation of the pattern formed on a substrate can be promoted, resulting in further miniaturization of the substrate and a further increase in functions per limited area.

From the viewpoint of acquiring the acid diffusion preventing effect more effectively, the polymer (B) is preferably a polymer that has substantially no acid-dissociable groups. The acid-dissociable group is described later. In addition, the polymer (B) is preferably a polymer that has substantially no crosslinking groups which crosslinks by the action of an acid.

There are no particular limitations to the polymer (B) so long as it has a nitrogen-containing group.

The nitrogen-containing group refers to a functional group having a nitrogen atom. Examples of the nitrogen-containing group include a group having a structure —NR²R³ (hereinafter, referred to as “amine group”), an azido group, an imido group, a urea group, a urethane group, a pyridine group, and the like.

Of these, an amine group is preferable. R² and R³ in the above-mentioned amine group individually are a hydrogen atom, a linear or branched hydrocarbon group having 1 to 10 carbon atoms, or a cyclic hydrocarbon group having 3 to 10 carbon atoms. In addition, R² and R³ may bond each other to form a 3 to 10 member monocyclic hetero ring or bond via at least one hetero atom selected from a nitrogen atom, an oxygen atom, a sulfur atom, and a selenium atom to form a 4 to 10 member monocyclic hetero ring.

When R² and R³ in the above-mentioned amine group is specifically a linear or branched hydrocarbon groups having 1 to 10 carbon atoms, examples of R² and R³ include an aliphatic hydrocarbon group such as methyl group, ethyl group, n-propyl group, isopropyl group, n-butyl group, 2-methylpropyl group, 1-methylpropyl group and tert-butyl group.

Additionally, when R² and R³ in the above-mentioned amine group is specifically a cyclic hydrocarbon groups having 3 to 10 carbon atoms, examples of R² and R³ include an alicyclic group such as cyclobutyl group, cyclopentyl group, cyclohexyl group, cycloheptyl group and cyclooctyl group; an aromatic group such as phenyl group, o-tolyl group, m-tolyl group, p-tolyl group, 4-tert-butyl phenyl group, 1-naphthyl group and benzyl group.

Further, when R² and R³ in the above-mentioned amine group bond each other to form a 3 to 10 member monocyclic hetero ring (which may be either an unsaturated ring or a saturated ring), examples of the amine group include an aziridino group, an azetino group, a pyrrolidino group, a pyrrole group, a piperidino group, a pyridino group, and the like.

Moreover, when R² and R³ in the above-mentioned amine group bond via at least one hetero atom selected from a nitrogen atom, an oxygen atom, a sulfur atom, and a selenium atom to form a 4 to 10 member monocyclic hetero ring (which may be either an unsaturated ring or a saturated ring), examples of the amine group include a morpholino group, a thiomorpholino group, a selenomorpholino group, an iso-oxazolidino group, an iso-oxazole group, an isothiazolidino group, an isothiazole group, an imidazolidino group, a piperazino group, a triazino group, and the like.

The amino group in the polymer (B) may be included in any form. The amino group may bond to either the main chain or the side chain of the polymer (B), but preferably to the side chain. That is to say, it is preferable that the polymer (B) have the nitrogen-containing group in the side chain. Additionally, the nitrogen-containing group is preferably contained in the polymer (B) as a structural unit represented by the following general formula (1).

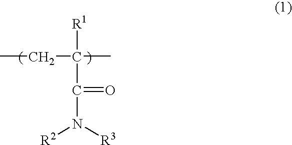

(In the formula, R¹ is a hydrogen atom or a methyl group, and R² and R³ individually are a hydrogen atom, a linear or branched hydrocarbon group having 1 to 10 carbon atoms, or a cyclic hydrocarbon group having 3 to 10 carbon atoms, or R² and R³ may bond to form a 3 to 10 membered monocyclic hetero ring containing a nitrogen atom, an oxygen atom, a sulfur atom or a selenium atom.)

When the polymer having the structural unit represented by the general formula (1) as the polymer (B) is contained in the acid transfer composition of the present invention, unnecessary diffusion of an acid in the resulting acid transfer film can be prevented in the case the acid is generated from the acid generator (A). That is to say, the polymer (B) can be functioned as a acid diffusion preventing resin. Thereby, unintended acid transfer (acid diffusion) to other layers can be prevented and the resolution of the resulting pattern can be promoted.

### 1-2-1. Structural Unit (1)

The structural unit (1) represented by the general formula (1) may be included in the polymer (B) in any form, however, the structural unit (1) can usually be formed by polymerizing a monomer (Bm1) represented by the following general formula (14).

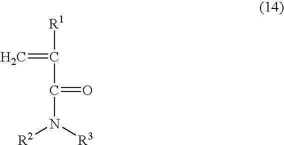

(In the formula, R¹ is a hydrogen atom or a methyl group, and R² and R³ individually are a hydrogen atom, a linear or branched hydrocarbon group having 1 to 10 carbon atoms, or a cyclic hydrocarbon group having 3 to 10 carbon atoms, or R² and R³ may bond to form a 3 to 10 membered monocyclic hetero ring containing a nitrogen atom, an oxygen atom, a sulfur atom or a selenium atom.)

Examples of the linear or branched alkyl group having 1 to 10 carbon atoms represented by R² and/or R³ in the general formula (14) include an aliphatic hydrocarbon group such as methyl group, ethyl group, n-propyl group, isopropyl group, n-butyl group, 2-methylpropyl group, 1-methylpropyl group and tert-butyl group.

Examples of the monomer (Bm1) in which R² and/or R³ in the general formula (14) is a linear or branched alkyl group having 1 to 10 carbon atoms include N,N-dimethyl (meth)acrylamide, N,N-diethyl (meth)acrylamide, N-isopropyl (meth)acrylamide and the like.

Examples of the cyclic hydrocarbon group having 3 to 10 carbon atoms represented by R² and/or R³ in the general formula (14) include an alicyclic group such as cyclobutyl group, cyclopentyl group, cyclohexyl group, cycloheptyl group and cyclooctyl group; an aromatic group such as phenyl group, o-tolyl group, m-tolyl group, p-tolyl group, 4-tert-butyl phenyl group, 1-naphthyl group and benzyl group.

Additionally, examples of the monomer (Bm1) comprising a 3 to 10 member monocyclic hetero ring which is formed by bonding of R² and R³ with each other, and has a nitrogen atom, an oxygen atom, a sulfur atom, or a selenium atom include N-(meth)acryloylmorpholine and the like.

The preferable monomer (Bm1) is N,N-dimethyl acrylamide, N,N-dimethyl methacrylamide, N-acryloylmorpholine and N-methacryloylmorpholine. When the polymer obtained using the monomer (Bm1) is used as the polymer (B), unnecessary diffusion of an acid in the resulting acid transfer film can be prevented in the case the acid is generated from the acid generator (A). Thereby, unintended acid transfer (acid diffusion) to other layers can be prevented and the resolution of the resulting pattern can be promoted.

The content of the structural unit represented by the general formula (1) in the polymer (B) is not particularly limited and is preferably in the range from 1% to 50% by mol, more preferably from 3% to 40% by mol, and particularly from 5% to 30% by mol based on 100% by mol of all structural units in the polymer (B). When the content of the structural unit represented by the general formula (1) constituting the polymer (B) is in the above range, unnecessary diffusion of an acid in the resulting acid transfer film can be prevented in the case the acid is generated from the acid generator (A). Thereby, unintended acid transfer (acid diffusion) to other layers can be prevented and the resolution of the resulting pattern can be promoted.

### 1-2-2. Structural Unit (2)

In addition to the above-mentioned structural unit represented by the general formula (1), the polymer (B) may comprise other structural units. The other structural units are preferably a structural unit (2) represented by the following general formula (2).

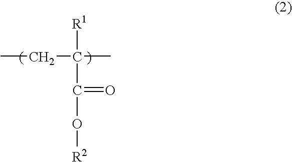

(In the formula, R¹ is a hydrogen atom or a methyl group, and R² is a monovalent organic group.)

The above-mentioned structural unit (2) represented by the general formula (2) may be included in the polymer (B) in any form, however, the structural unit (2) can usually be formed by polymerizing a monomer (Bm2) represented by the following general formula (15).

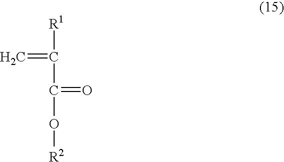

(In the formula, R¹ is a hydrogen atom or a methyl group, and R² is a monovalent organic group.)

Examples of the monovalent organic group represented by R² in the general formula (15) include a linear or branched alkyl group having 1 to 12 carbon atoms such as methyl group, ethyl group, n-propyl group, isopropyl group, n-butyl group, 2-methylpropyl group, 1-methylpropyl group and tert-butyl group; an aromatic hydrocarbon group (particularly those having 6 to 20 carbon atoms) such as phenyl group, o-tolyl group, m-tolyl group, p-tolyl group, 2,4-xylyl group, 2,6-xylyl group, 3,5-xylyl group, mesityl group, o-cumenyl group, m-cumenyl group, p-cumenyl group, benzyl group, phenetyl group, 1-naphthyl group and 2-naphthyl group; a hydroxylalkyl group (particularly those having 1 to 8 carbon atoms) such as hydroxymethyl group, 1-hydroxyethyl group, 2-hydroxyethyl group, 1-hydroxypropyl group, 2-hydroxypropyl group, 3-hydroxypropyl group, 1-hydroxybutyl group, 2-hydroxybutyl group, 3-hydroxybutyl group, 4-hydroxybutyl group, 3-hydroxycyclopentyl group and 4-hydroxycyclohexyl group; a nitrogen-containing organic group (particularly those having 2 to 9 carbon atoms) such as cyano group and a cyanoalkyl group including cyanomethyl group, 1-cyanoethyl group, 2-cyanoethyl group, 1-cyanopropyl group, 2-cyanopropyl group, 3-cyanopropyl group, 1-cyanobutyl group, 2-cyanobutyl group, 3-cyanobutyl group, 4-cyanobutyl group, 3-cyanocyclopentyl group and 4-cyanocyclohexyl group; a cyclic hydrocarbon group such as cyclopentyl group and cyclohexyl group; and a bridged cyclic hydrocarbon group such as bornyl group and isobornyl group.

R² in the general formula (15) may be a later-described acid-dissociable group, but is preferably not an acid-dissociable group.

The monomer (Bm2) is preferably a (meth)acrylate compound. Specific example thereof includes methyl (meth)acrylate, ethyl (meth)acrylate, n-propyl (meth)acrylate, n-butyl (meth)acrylate, 2-hydroxyethyl (meth)acrylate, 2-hydroxypropyl (meth)acrylate, polyethylene glycol mono(meth)acrylate, polypropylene glycol mono(meth)acrylate, glycerol mono(meth)acrylate, phenyl (meth)acrylate, benzyl (meth)acrylate, cyclohexyl (meth)acrylate, isobornyl (meth)acrylate, tricyclodecanyl (meth)acrylate and the like. These (meth)acrylate compounds may be used singly or in combination of two or more types thereof.

Among these (meth)acrylate compounds, methyl methacrylate is preferred.

The content of the structural unit represented by the general formula (2) in the polymer (B) is not particularly limited and is preferably in the range from 5% to 99% by mol, more preferably from 10% to 97% by mol, and particularly from 15% to 95% by mol based on 100% by mol of all structural units in the polymer (B). When the content of the structural unit represented by the general formula (2) constituting the polymer (B) is in the above range, unnecessary diffusion of an acid in the resulting acid transfer film can be prevented in the case the acid is generated from the acid generator (A). Thereby, unintended acid transfer (acid diffusion) to other layers can be prevented and the resolution of the resulting pattern can be promoted.

### 1-2-3. Other Structural Units

In addition to the above-mentioned structural units represented by the general formulae (1) and (2), the polymer (B) may contain other structural units. Any types of structural units may be used as the other structural units insofar as the object of the present invention is not impaired. In the case where the other structural units are included, the content thereof is not particularly limited and is preferably not more than 30% by mol, and more preferably in the range from 1% to 10% by mol based 100% by mol of all structural units. The other structural units in this range do not affect the object of the present invention.

When the above-mentioned structural units represented by the general formulae (1) and (2) and the other structural units are included, the content of the structural unit represented by the general formula (1) is preferably in the range from 1% to 50% by mol, more preferably from 3% to 40% by mol, and particularly from 5% to 30% by mol based on 100% by mol of the total of the above-mentioned structural units represented by the general formulae (1) and (2). When the contents of the structural units are in the above range, unnecessary diffusion of an acid in the resulting acid transfer film can be prevented in the case the acid is generated from the acid generator (A). Thereby, unintended acid transfer (acid diffusion) to other layers can be prevented and the resolution of the resulting pattern can be promoted.

The molecular weight of the polymer (B) is not particularly limited and may be appropriately selected. The polystyrene-reduced weight average molecular weight (hereinafter, referred to as “Mw”) determined by gel permeation chromatography (GPC) for the polymer (B) is usually in the range from 1,000 to 500,000, preferably from 2,000 to 400,000, and further preferably from 3,000 to 300,000.

The ratio (Mw/Mn) that is calculated from the above-mentioned Mw and the polystyrene-reduced number average molecular weight (hereinafter, referred to as “Mn”) determined by GPC for the polymer (B) is not particularly limited and may be appropriately selected. It is usually in the range from 1 to 10, preferably from 1 to 8, and further preferably from 1 to 3.

### 1-3. Ketone-Based Solvent (C)

The ketone-based solvent (C) is a component which functions as a solvent for both the acid generator (A) and the polymer (B), and has a structure represented by the following general formula (16).

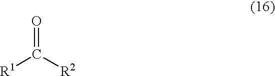

(In the formula, R¹ and R² bond together to form a divalent cyclic hydrocarbon group having 5 to 9 carbon atoms or individually are a monovalent hydrocarbon group having 1 to 6 carbon atoms.)

In the composition of the present invention, since the ketone-based solvent (C) is contained, the solvent can be easily removed from the coating obtained using the composition as compared with the case in which other solvents are used. In particular, the solvent can be simply and sufficiently removed by prebaking. Therefore, the amount of the solvent remaining in the acid transfer film can be reduced to provide conditions in the film under which the acid generator (A) and the polymer (B) function more easily. It is thus possible to provide more uniform diffusion of an acid generated by exposure, while suppressing unnecessary diffusion of the acid. As a result, excellent in-plane dimensional uniformity (dimensional accuracy in a plane) can be secured.

Examples of the cycloketone compound in which R¹ and R² bond together to form a divalent cyclic hydrocarbon group having 5 to 9 carbon atoms include cyclopentanone, 3-methylcyclopentanone, cyclohexanone, 2-methylcyclohexanone, 2,6-dimethylcyclohexanone, isophorone, and the like. These cycloketone compounds may be used singly or in combination of two or more types thereof.

Additionally, examples of the ketone compound (noncyclic ketone compound) in which R¹ and R² individually are a hydrocarbon group having 1 to 6 carbon atoms include 2-butanone, 2-pentanone, 3-methyl-2-butanone, 2-hexanone, 4-methyl-2-pentanone, 3-methyl-2-pentanone, 3,3-dimethyl-2-butanone, 2-heptanone, 2-octanone and the like. These ketone compounds may be used singly or in combination of two or more types thereof.

Further, the above-mentioned cycloketone compound and noncyclic ketone compound may be used in combination.

From the viewpoint of in-plane dimensional uniformity, a cycloketone compound is more preferable as the ketone-based solvent (C). Among the compound, cyclohexanon and cyclopentanone are preferable and cyclohexanone is particularly preferred. These preferable ketone-based solvents have a high vapor pressure and capability of effectively reducing the residual amount of the solvent after prebaking in addition to the other necessary properties.

The content of the ketone-based solvent (C) in the composition of the present invention is not particularly limited and is usually in the range from 10 to 10,000 parts by weight, preferably from 20 to 8,000, more preferably from 30 to 6,000, and further preferably from 40 to 4,000 based on 100 parts by weight of the polymer (B).

The viscosity of the acid transfer composition is not particularly limited and may be appropriately adjusted according to the method of applying the acid transfer composition and the like. For example, the viscosity at a temperature of 25° C. may be in the range from 1 to 100 mPa·s. The viscosity thereof is preferably from 2 to 80 mPa·s, and more preferably from 3 to 50 mPa·s.

In the composition of the present invention, the ketone-based solvent (C) can be used with other solvent (C′).

Examples of the other solvent (C′) include a propylene glycol monoalkyl ether acetate, an alkylether, an alkyl alcohol, a hydrocarbon and the like.

Examples of the propylene glycol monoalkyl ether acetate include propylene glycol monomethyl ether acetate, propylene glycol monoethyl ether acetate, propylene glycol mono-n-propyl ether acetate, propylene glycol mono-isopropyl ether acetate, propylene glycol mono-n-butyl ether acetate, propylene glycol mono-isobutyl ether acetate, propylene glycol mono-sec-butyl ether acetate, propylene glycol mono-tert-butyl ether acetate and the like.

Examples of the alkyl ether include propylene glycol monomethyl ether, propylene glycol monoethyl ether, ethylene glycol monomethyl ether, ethylene glycol monoethyl ether, ethylene glycol dimethyl ether, ethylene glycol diethyl ether, diethylene glycol monomethyl ether, diethylene glycol mono ethyl ether, diethylene glycol dimethyl ether, diethylene glycol diethyl ether, diethylene glycol ethyl methyl ether, dipropyl ether, diisopropyl ether, butyl methyl ether, butyl ethyl ether, butyl propyl ether, dibutyl ether, diisobutyl ether, tert-butyl-methyl ether, tert-butyl ethyl ether, tert-butyl propyl ether, di-tert-butyl ether, dipentyl ether, diisoamyl ether, cyclopentyl methyl ether, cyclohexyl methyl ether, cyclopentyl ethyl ether, cyclohexyl ethyl ether, cyclopentyl propyl ether, cyclopentyl 2-propyl ether, cyclohexyl propyl ether, cyclohexyl 2-propyl ether, cyclopentyl butyl ether, cyclopentyl tert-butyl ether, cyclohexyl butyl ether, cyclohexyl tert-butyl ether and the like.

Examples of the alkyl alcohol include 1-propanol, n-butanol, 2-butanol, 1-pentanol, 2-pentanol, 3-pentanol, 2-methyl-1-propanol, neopentyl alcohol, tert-amyl alcohol, isoamyl alcohol, 3-methyl-2-butanol, 2-methyl-1-butanol, 2-ethyl-1-butanol, 2-methyl-1-pentanol, 4-methyl-2-pentanol, 1-octanol, 1-nonanol and the like.

Examples of the hydrocarbon include decane, dodecane, undecane, benzene, toluene, xylene and the like.

Examples of the other solvents include ethyl 2-hydroxy-2-methylpropionate, ethyl ethoxyacetate, ethyl hydroxyacetate, methyl 2-hydroxy-3-methylbutyrate, 3-methoxybutyl acetate, 3-methyl-3-methoxybutyl acetate, 3-methyl-3-methoxybutyl propionate, 3-methyl-3-methoxybutyl butyrate, ethyl acetate, n-propyl acetate, n-butyl acetate, methyl acetoacetate, ethyl acetoacetate, methyl pyruvate, ethyl pyruvate, N-methylpyrrolidone, N,N-dimethylformamide, N,N-dimethylacetamide, benzyl ethyl ether, caproic acid, caprylic acid, benzyl acetate, ethyl benzoate, diethyl oxalate, diethyl maleate, γ-butyrolactone, ethylene carbonate, propylene carbonate and the like.

The other solvent (C′) may be used singly or in combination of two or more types thereof.

Among the other solvent (C′), γ-butyrolactone and propylene glycol monomethyl ether acetate are preferred.

### 1-4. Surfactant (D)

The acid transfer composition of the present invention may contain other components in addition to the acid generator (A), the polymer (B), the ketone-based solvent (C), and the other solvents (C′). The other components include a surfactant (hereinafter, referred to as “Surfactant (D)”). Examples of the surfactant (D) include a nonionic surfactant, an anionic surfactant, a cationic surfactant, an amphoteric surfactant, a silicon-based surfactant, a polyalkylene oxide-based surfactant, a fluorine-based surfactant and the like. These surfactants (D) may be used singly or in combination of two or more types thereof.

Specific examples of the surfactant (D) include polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate; commercially available products such as “NBX-7”, “NBX-8” and “NBX-15” (manufactured by Neos Co., Ltd.), “SH8400 FLUID” (manufactured by Toray Dow Corning Silicone Co.), “KP341” (manufactured by Shin-Etsu Chemical Co., Ltd.), “Polyflow No. 75” and “Polyflow No. 95” (manufactured by Kyoeisha Chemical Co., Ltd.), “FTOP EF301”, “FTOP EF303” and “FTOP EF352” (manufactured by JEMCO, Inc.), “MEGAFAC F171”, “MEGAFAC F172”, “MEGAFAC F173”, “MEGAFAC F471”, “MEGAFAC R07” and “MEGAFAC R08”, (manufactured by Dainippon Ink and Chemicals, Inc.), “Fluorad FC430” and “Fluorad FC431”, (manufactured by Sumitomo 3M Ltd.), “Asahi Guard AG710”, “Surflon S-382”, “Surflon SC-101”, “Surflon SC-102”, “Surflon SC-103”, “Surflon SC-104”, “Surflon SC-105” and “Surflon SC-106” (manufactured by Asahi Glass Co., Ltd.), and the like.

When the surfactant (D) is used for the composition of the present invention, the formulating amount thereof is not particularly limited and is usually in the range from 0.01 to 0.5 parts by weight and preferably from 0.02 to 0.1 part by weight based on 100 parts by weight of the polymer (B).

### 1-5. Sensitizer (E)

The acid transfer composition of the present invention may contain other components in addition to the acid generator (A), the polymer (B), the ketone-based solvent (C), the other solvents (C′), and the surfactant (D). The other components include a sensitizer (hereinafter, referred to as “sensitizer (E)”).

Examples of the sensitizer (E) include a thioxanethone such as thioxanthen-9-on and its derivatives, anthracene and its derivatives, and the like. These sensitizer (E) may be used singly or in combination of two or more types thereof. Among these sensitizers (E), thioxanethone and its derivatives are preferable, and a compound represented by the following general formula (20) is particularly preferable. When the sensitizer (E) represented by the following general formula (20) is used in combination with the polymer (B), excellent optical sensitization properties can be obtained.

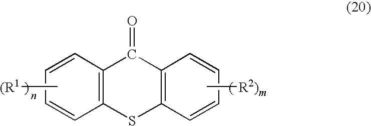

(In the formula, R¹ and R² individually are an alkyl group or a halogen atom, and n and m individually are integers from 1 to 4.)

In the general formula (20), R¹ and R² may be either the same or different. In addition, n and m may also be either the same or different. The alkyl group for R¹ and R² in the general formula (20) may be a linear alkyl group, a branched alkyl group, or a cycloalkyl group. The number of the carbon atoms for the alkyl group is not particularly limited. When the alkyl group is a linear or branched alkyl group, the number of carbon atoms is preferably in the range from 1 to 14. When it is a cycloalkyl group, the number of carbon atoms is preferably in the range from 4 to 20.

Examples of the linear or branched alkyl group having 1 to 14 carbon atoms include methyl group, ethyl group, n-propyl group, isopropyl group, n-butyl group, isobutyl group, tert-butyl group, tert-pentyl group, hexyl group, heptyl group, octyl group, nonyl group, decyl group, undecyl group, dodecyl group and the like. In addition, examples of the cycloalkyl group having 4 to 20 carbon atoms include cyclohexyl group and the like.

When R¹ and R² in the general formula (20) are a halogen atom, example thereof include chlorine atom, bromine atom, iodine atom and the like.

Examples of the sensitizer (E) represented by the general formula (20) include thioxanethone, 2-isopropylthioxanthone represented by the following formula (20-1), 2,4-dimethylthioxanthone, 2,4-diethylthioxanthone represented by the following formula (20-2), 2-chlorothioxanthone, 2-dodecylthioxanethone, 1-chloro-4-isopropylthioxanthone represented by the following formula (20-3), 2-cyclohexylthioxanethone represented by the following formula (20-4), and the like. Among these, 2-isopropylthioxanthone, 2,4-diethylthioxanthone, 1-chloro-4-isopropylthioxanthone, and 2-cyclohexylthioxanethone are preferable.

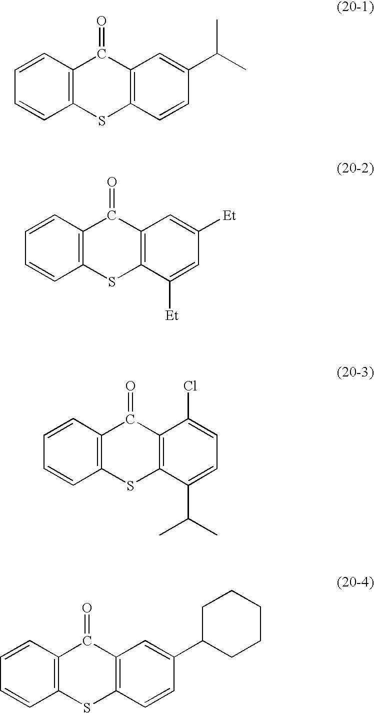

In the case where the composition of the present invention comprises the sensitizer (E), the content thereof is not particularly limited and is usually in the range from 1 to 500 parts by weight based on 100 parts by weight of the acid generator (A) from the viewpoint of sufficiently ensuring acid transferring capability as an acid transfer film (second resin film). The preferable content thereof is in the range from 10 to 300 parts by weight and more preferable content thereof is from 20 to 200 parts by weight from the viewpoint of ensuring more excellent acid transferring capability by a combination of the sensitizer (E) and the acid generator (A).

### 1-6. Other Components

The acid transfer composition of the present invention may contain other components in addition to the acid generator (A), the polymer (B), the ketone-based solvent (C), the other solvents (C′), the surfactant (D) and the sensitizer (E). The other components include a crosslinking agent, a halation preventive, a storage stabilizer, a coloring agent, a plasticizer, an anti-foaming agent, and the like.

### 2. Acid Transfer Film

The acid transfer film of the present invention is characterized in that the film is by formed using the acid transfer composition of the present invention.

The acid transfer film of the present invention is a film obtained using a composition which contains the acid generator (A), the polymer (B) and the ketone-based solvent (C) at least. The above descriptions for the acid generator (A) and the polymer (B) apply as is to the acid generator (A) and the polymer (B) used here.

The acid transfer film of the present invention may be formed in any manner so long as the acid transfer composition is used. The acid transfer film may be formed by applying the acid transfer composition containing the ketone-based solvent (C) and removing a part or all of the ketone-based solvent (C).

The method for removing the ketone-based solvent (C) is not particularly limited and examples include a removing method with heating, a removing method under reduced pressure, a spontaneous removing method and the like. These methods may be combined with each other.

### 3. Pattern Forming Method

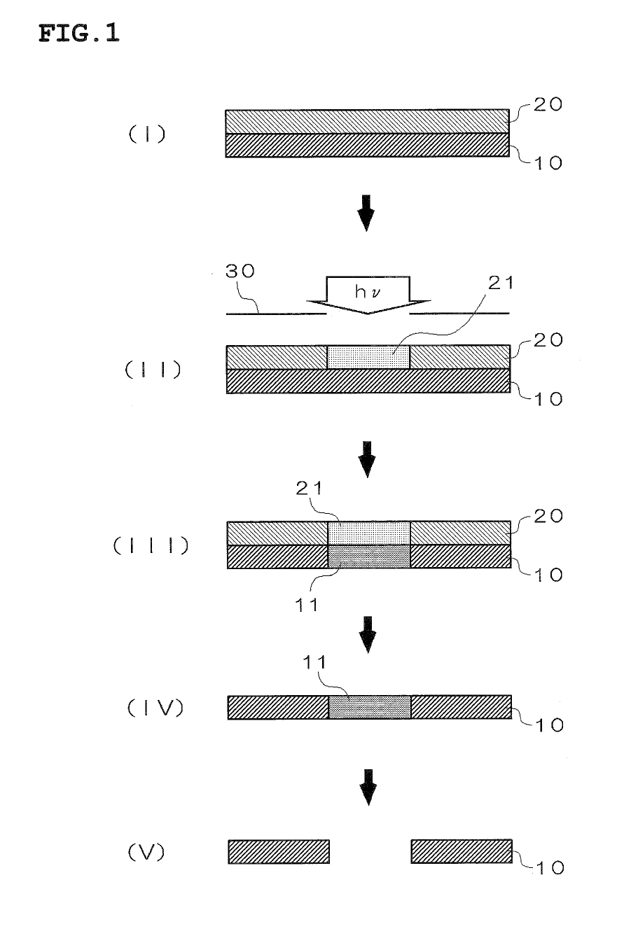

The pattern forming method of the present invention is characterized by comprising the following processes in the following order, as shown in FIG. 1, (I) a second resin film formation process for forming a second resin film 20 as an acid transfer film on a first resin film using the acid transfer composition of the present invention, the first resin film 10 comprising an acid-dissociable group-containing resin, but not comprising a radiation-sensitive acid generator, (II) an exposure process for exposing the second resin film 20 to a light through a mask 30 to generate an acid in the second resin film 20, (III) an acid transfer process for transferring the acid generated in the second resin film 20 to the first resin film 10, and (IV) a second resin film removing process for removing the second resin film 20.

### 3-1. Second Resin Film Formation Process (I)

The second resin film formation process (I) is a process wherein a second resin film that is an acid transfer film is formed on a first resin film that is a patterning target resin film.

### 3-1-1. First Resin Film (Patterning Target Resin Film)

The first resin film is a resin film that contains a resin having an acid-dissociable group (hereinafter, referred to as “acid-dissociable group-containing resin”), but does not contain a radiation-sensitive acid generator. In addition, the first resin film is usually insoluble or scarcely soluble in alkali, but becomes alkali-soluble when the acid-dissociable group in the acid-dissociable group-containing resin dissociates. The term “insoluble or scarcely soluble in alkali” herein used refers to the properties of a film made only of an acid dissociable group-containing resin to keep 50% or more of its initial thickness when developed under alkali development conditions defined in the later-described example. The term “alkali-soluble” refers to the properties of such a film in which more than 50% of its thickness is dissolved under the above conditions.

The first resin film herein used includes a resin film before patterning (a patterning target resin film), and a resin film after patterning (patterned resin film). Specifically, the first resin film is converted into a “pattern” which has a part in which an acid has not been transferred and a part in which the acid has been transferred by the processes (I) to (IV). Furthermore, when the development process (V) is optionally performed for the removal of the acid-transferred part, a “pattern” can be formed which consists of a part in which the acid has not been transferred and a part in which the layer comprising the acid has been removed (a part in which the surface of a substrate is exposed when the substrate is provided in an underlayer).

The acid-dissociable group refers to a group which dissociates in the presence of an acid and is capable of replacing with a hydrogen atom in an acidic group such as a phenolic hydroxyl group, a carboxyl group and a sulfonic group. Examples of the acid-dissociable group include t-butoxycarbonyl group, tetrahydropyranyl group, tetrahydrofuranyl group, (thiotetrahydropyranylsulfanyl)methyl group, (thiotetrahydrofuranylsulfanyl)methyl group, an alkoxy-substituted methyl group, an alkylsulfanyl-substituted methyl group, a group represented by the following general formula (17) (hereinafter, referred to as “acid-dissociable group (17)”), and the like.

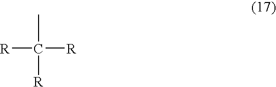

(In the formula, R individually is a linear or branched alkyl group having 1 to 14 carbon atoms or a bridged or nonbridged monovalent alicyclic hydrocarbon group having 3 to 20 carbon atoms, or any two of the groups R bond to form a bridged or nonbridged divalent alicyclic hydrocarbon group having 3 to 20 carbon atoms, with the remaining R being a linear or branched alkyl group having 1 to 14 carbon atoms or a bridged or nonbridged monovalent alicyclic hydrocarbon group having 3 to 20 carbon atoms, wherein all these groups may be either substituted or unsubstituted.)

Examples of the alkoxy-substituted methyl group include methoxy methyl group, ethoxy methyl group, methoxy ethoxy methyl group, n-propoxy methyl group, n-butoxy methyl group, n-pentyloxy methyl group, n-hexyloxy methyl group, benzyloxy methyl group and the like.

Examples of the alkylsulfanyl-substituted methyl group include methyl sulfanyl methyl group, ethyl sulfanyl methyl group, methoxyethyl sulfanyl methyl group, n-propyl sulfanyl methyl group, n-butyl sulfanyl methyl group, n-pentyl sulfanyl methyl group, n-hexyl sulfanyl methyl group, benzyl sulfanyl methyl group and the like.

When R in the general formula (17) is a linear or branched alkyl group having 1 to 14 carbon atoms, example thereof includes methyl group, ethyl group, n-propyl group, isopropyl group, n-butyl group, 2-methyl propyl group, n-pentyl group, n-hexyl group, n-heptyl group, n-octyl group, n-nonyl group, n-decyl group, n-undecyl group, n-dodecyl group, n-tridecyl group, n-tetradecyl group and the like.

When the abovementioned alkyl group is an alkyl group having a substituent, example thereof include a hydroxyl group, a carboxyl group, an oxo group (═O), a cyano group, a halogen atom such as fluorine atom and chlorine atom, a linear or branched alkoxyl group having 1 to 8 carbon atoms such as methoxy group, ethoxy group, n-propoxy group, isopropoxy group, n-butoxy group, 2-methylpropoxy group, 1-methylpropoxy group, and tert-butoxy group, a linear or branched alkoxyalkoxyl group having 2 to 8 carbon atoms such as methoxymethoxy group, ethoxymethoxy group, and tert-butoxymethoxy group, a linear or branched alkylcarbonyloxy group having 2 to 8 carbon atoms such as methylcarbonyloxy group, ethylcarbonyloxy group and tert-butylcarbonyloxy group, a linear or branched alkoxycarbonyl group having 2 to 8 carbon atoms such as methoxycarbonyl group, ethoxycarbonyl group and tert-butoxycarbonyl group, and the like. The above-mentioned alkyl group may have one substituent or two or more substituents.

Additionally, when R in the general formula (17) is a bridged or nonbridged monovalent alicyclic hydrocarbon group having 3 to 20 carbon atoms, example thereof include a cycloalkyl group such as cyclopropyl group, cyclobutyl group, cyclopentyl group, cyclohexyl group, cycloheptyl group and cyclooctyl group, bicyclo[2.2.1]heptyl group, bicyclo[2.2.2]octyl group, tetracyclo[4.2.0.1^{2.5}.1^{7.10}]dodecyl group, adamantyl group and the like.

Further, in the general formula (17), when R is a monovalent alicyclic group or when a divalent alicyclic group is formed by bonding of any two of the groups R, and R has a substituent, example thereof includes a hydroxyl group, a carboxyl group, an oxo group (═O), a cyano group, a halogen atom such as fluorine atom and chlorine atom, a linear or branched alkyl group having 1 to 14 carbon atoms such as methyl group, ethyl group, n-propyl group, isopropyl group, n-butyl group, 2-methylpropyl group, 1-methylpropyl group and tert-butyl group, a linear or branched alkoxyl group having 1 to 8 carbon atoms such as methoxy group, ethoxy group, n-propoxy group, isopropoxy group, n-butoxy group, 2-methylpropoxy group, 1-methylpropoxy group and tert-butoxy group, a linear or branched alkoxyalkyl group having 2 to 8 carbon atoms such as methoxymethyl group, ethoxymethyl group and tert-butoxymethyl group, a linear or branched alkoxyalkoxyl group having 2 to 8 carbon atoms such as methoxymethoxy group, ethoxymethoxy group and tert-butoxymethoxy group, a linear or branched alkylcarbonyloxy group having 2 to 8 carbon atoms such as methylcarbonyloxy group, ethylcarbonyloxy group and tert-butylcarbonyloxy group, a linear or branched alkoxycarbonyl group having 2 to 8 carbon atoms such as methoxycarbonyl group, ethoxycarbonyl group and tert-butoxycarbonyl group, a linear or branched cyanoalkyl group having 2 to 14 carbon atoms such as cyanomethyl group, 2-cyanoethyl group, 3-cyanopropyl group and 4-cyanobutyl group, a linear or branched fluoroalkyl group having 1 to 14 carbon atoms such as fluoromethyl group, trifluoromethyl group and pentafluoroethyl group, and the like. The above-mentioned monovalent alicyclic group and divalent alicyclic group may have one substituent or two or more substituents.

Specific examples of the acid-dissociable group (17) include tert-butyl group, groups represented by the following general formulae (17-1) to (17-20) (provided that m is an integer from 0-2) and the like.

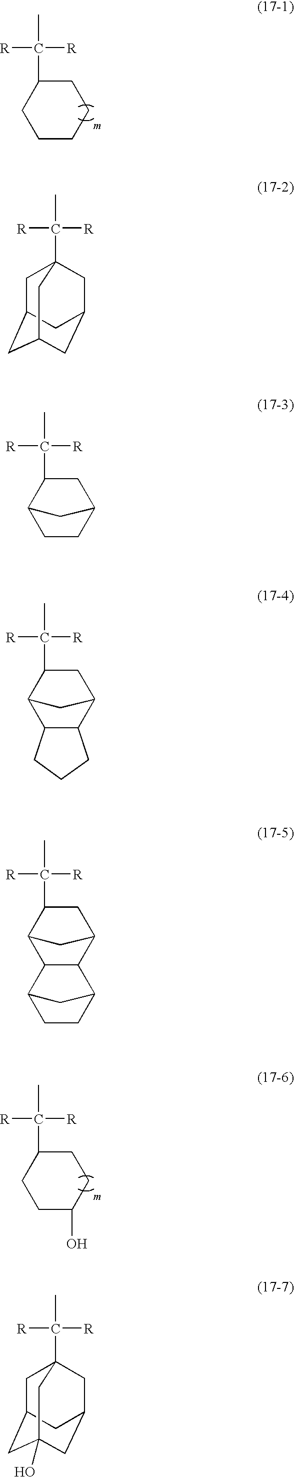

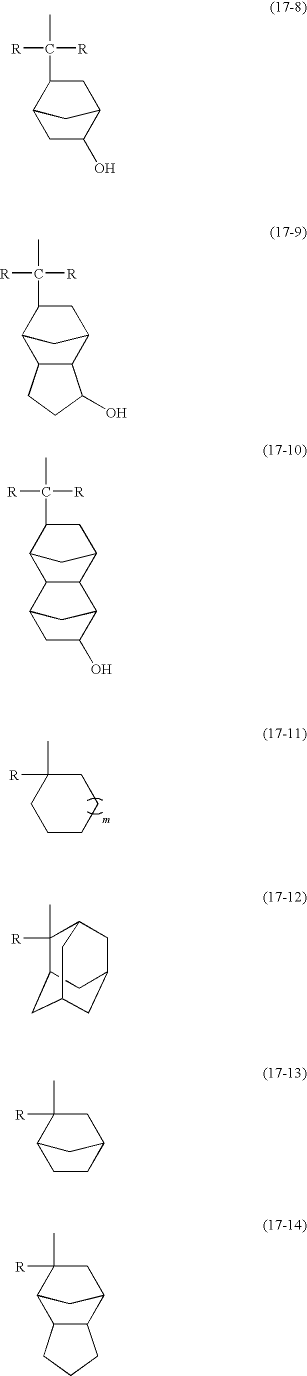

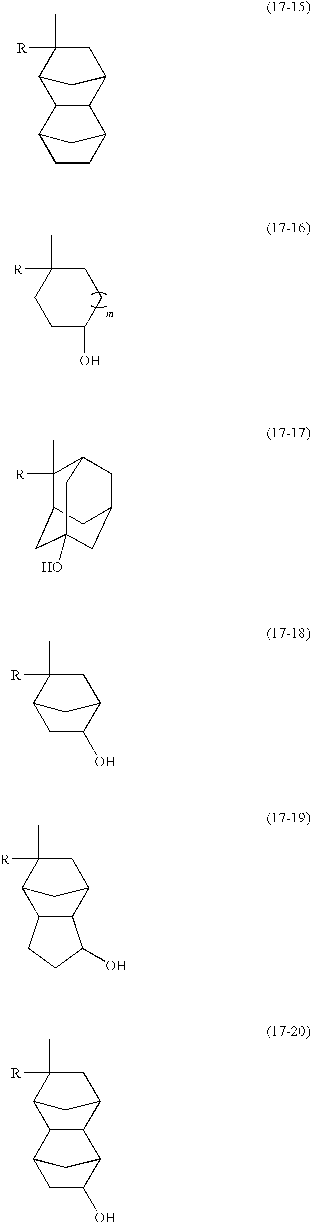

Although an acid-dissociable group may be included in the acid-dissociable group-containing resin in any form, it is preferable that the acid-dissociable group be included as a part of a structural unit (hereinafter, referred to simply as “acid-dissociable group-containing unit”) represented by the following general formula (18).

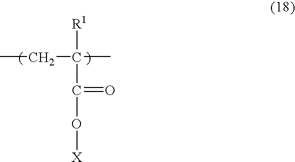

(In the formula, R¹ is a hydrogen atom or a methyl group and X is an acid-dissociable group.)

The above-mentioned acid-dissociable group-containing unit may be included in the acid-dissociable group-containing resin in any form, however, the structural unit can be formed by polymerizing a monomer having an acid-dissociable group. Examples of the monomer having an acid-dissociable group include tert-butyl (meth)acrylate, 1,1-dimethylpropyl (meth)acrylate, 1,1-dimethylbutyl (meth)acrylate, 2-cyclohexylpropyl (meth)acrylate, 1,1-dimethylphenyl (meth)acrylate, tetrahydropyranyl (meth)acrylate, 2-tert-butoxycarbonylmethyl (meth)acrylate, 2-benzyloxycarbonylethyl (meth)acrylate, 2-methyladamantyl (meth)acrylate, 1,1-dimethyl-3-oxobutyl (meth)acrylate, 2-benzylpropyl (meth)acrylate and the like.

The content of the acid-dissociable group-containing unit in the acid-dissociable group-containing resin is not particularly limited and is preferably in the range from 5% to 95% by mol, more preferably from 10% to 90% by mol, and particularly from 15% to 80% by mol based on 100% by mol of all structural units constituting the acid-dissociable group-containing resin. When the content of the acid-dissociable group-containing unit in the acid-dissociable group-containing resin is in the above range, a sufficient exposure margin (exposure allowance) can be secured.

Additionally, the acid-dissociable group-containing resin usually has other structural units. Example thereof includes a structural unit having an acidic group such as phenolic hydroxyl group. When the acid-dissociable group-containing resin has a structural unit having an acidic group, the solubility of the first resin film in a developer can be adjusted in the case where the present method comprises a development process (V) after the second resin film removing process (IV). Examples of a monomer providing a structural unit having a phenolic hydroxyl group include a phenolic hydroxyl group-containing compound such as p-isopropenyl phenol, m-isopropenyl phenol, o-isopropenyl phenol, p-hydroxy styrene, m-hydroxy styrene and o-hydroxystyrene. The phenolic hydroxyl group-containing compound may be used singly or in combination of two or more types thereof.

When the acid-dissociable group-containing resin contains a structural unit derived from a phenolic hydroxyl group-containing compound, the content thereof is not particularly limited. The content is preferably in the range from 1% to 50% by mol, more preferably from 3% 45% by mol, and particularly from 5% to 40% by mol based on 100% by mol of all structural units constituting the acid-dissociable group-containing resin. When the content of the structural unit derived from a phenolic hydroxyl group-containing compound in the acid-dissociable group-containing resin is in the above range, the solubility (alkali solubility) of the resin film in a developer can be easily adjusted in the development process (V).

The content of the acid-dissociable group-containing resin in the first resin film is not particularly limited and is preferably in the range from 10% to 99.9% by weight, more preferably from 30% to 99.9% by weight, and particularly from 50% to 99.9% by weight based on 100% by weight of the first resin film. When the content of the acid-dissociable group-containing resin in the first resin film is in the above range, it is possible to provide solubility (alkali solubility) contrast or a solubility difference in a developer in the development process (V).

When the acid-dissociable group-containing resin is prepared by polymerization of a polymerizable unsaturated monomer or a method comprising the polymerization, a branched structure based on a polyfunctional monomer having two or more polymerizable unsaturated bonds and/or an acetal crosslinking group may be introduced into the acid-dissociable group-containing resin. Introduction of such a branched structure leads to improvement of the heat resistance of the acid-dissociable group-containing resin.

The introduction amount of the branched structure into the acid-dissociable group-containing resin may be appropriately selected according to the branched structure and types of the resin. The amount thereof is preferably 10% or less by mol based on the total amount of structural units.

The molecular weight of the acid-dissociable group-containing resin is not particularly limited and may be appropriately selected. The polystyrene-reduced weight average molecular weight (Mw) determined by GPC for the acid-dissociable group-containing resin is usually in the range from 1,000 to 500,000, preferably from 2,000 to 400,000, and further preferably from 3,000 to 300,000.

The ratio (Mw/Mn) that is calculated from the above-mentioned Mw and the polystyrene-reduced number average molecular weight (Mn) determined by GPC for the acid-dissociable group-containing resin is not particularly limited and may be appropriately selected. It is usually in the range from 1 to 10, preferably from 1 to 8, and further preferably from 1 to 5.

A method for the production of the acid-dissociable group-containing resin is not particularly limited and example thereof includes a method a method of introducing one or more acid-dissociable groups into an acidic group of an alkali-soluble resin which has previously been manufactured, a method of polymerizing one or more polymerizable unsaturated monomers having an acid-dissociable group, optionally together with other polymerizable unsaturated monomers, a method of polycondensing one or more polycondensable components having an acid-dissociable group, optionally together with other polycondensable components, and the like.

The polymerization of the polymerizable unsaturated monomers and the polymerization of the one or more polymerizable unsaturated monomers possessing an acid-dissociable group in the manufacture of an alkali soluble resin is carried out by block polymerization, solution polymerization, precipitation polymerization, emulsion polymerization, suspension polymerization, block-suspension polymerization, or the like using an appropriate polymerization initiator or catalyst such as a radical polymerization initiator, an anionic polymerization catalyst, a coordinated anionic polymerization catalyst, a cationic polymerization catalyst, or the like according to the type of polymerizable unsaturated monomer or reaction media.

The polycondensation of the one or more polycondensable components having an acid-dissociable group is preferably carried out in the presence of an acidic catalyst using an aqueous medium or a mixture of water and a hydrophilic solvent.

There are no particular limitations on the method for forming the first resin film, however, the first resin film can be formed by applying a liquid composition for forming a first resin film (first resin film forming composition) on the surface of a substrate and drying the coating. When a solvent is contained in the first resin film forming composition comprising the acid-dissociable group-containing resin, the composition can be a liquid.

Examples of the solvent include the above-mentioned ketone-based solvent (C) and the other solvents (C′). The solvent may be used singly or in combination of two or more types thereof. The solvent used for the first resin film forming composition and the solvent used for the acid transfer composition may be either the same or different.

When the first resin film forming composition contains a solvent, the content of the solvent is usually in the range from 10 to 10,000 parts by weight, preferably from 20 to 8,000 parts by weight, more preferably from 30 to 6,000 parts by weight, and further preferably from 40 to 4,000 parts by weight based on 100 parts by weight of the acid-dissociable group-containing resin.

Additionally, the viscosity of the first resin film forming composition is not particularly limited and may be appropriately adjusted according to the method of applying the composition and the like. The viscosity thereof may for example be in the range from 1 to 100 mPa·s at 25° C. The viscosity is preferably from 2 to 80 mPa·s, and more preferably from 3 to 50 mPa·s.

The first resin film forming composition may contain other components in addition to the solvent. The other components include a surfactant. As the surfactant, the above-mentioned surfactant (D) can be used as is. The surfactant may be used singly or in combination of two or more types thereof. The surfactant used for the first resin film forming composition and the surfactant used for the acid transfer composition may be either the same or different.

When the first resin film forming composition contains a surfactant, the content of the surfactant is not particularly limited and is usually in the range from 0.01 to 1 part by weight and preferably from 0.02 to 0.8 part by weight based on 100 parts by weight of the acid-dissociable group-containing resin.

In addition, other additives such as a crosslinking agent, a halation preventive, a storage stabilizer, a coloring agent, a plasticizer and an anti-foaming agent may be incorporated to the first resin film forming composition as appropriate.

The first resin film may be formed on the surface of any material. The first resin film is usually formed on the surface of a substrate. Examples of a material of the substrate (at least a surface material) include silicon, a metal such as aluminum, a metal spatter film such as aluminum film, alumina, glass epoxy, paper phenol, glass and the like. The thickness of the substrate is usually in the range from 1,000 to 10,000 nm.

The thickness of the first resin film formed is not particularly limited and is usually in the range from 1 to 1,000 nm, preferably from 5 to 500 nm, and more preferably from 10 to 100 nm.

The method for the application of the first resin film forming composition is not particularly limited and example thereof includes a rotation application, a cast coating, a roll application, and the like.

After applying the first resin film forming composition, the coating may optionally be prebaked (PB) to vaporize the solvent contained therein to form a first resin film. The heating conditions for PB may be appropriately selected according to the composition of the first resin film forming composition. The heating temperature is usually in the range from about 30° C. to 150° C., and preferably from 50° C. to 130° C. The heating time is usually in the range from 30 to 300 seconds, and preferably from 60 to 180 seconds.

### 3-1-2. Second Resin Film (Acid Transfer Film)

The second resin film (acid transfer film) is a resin film 20 formed on the first resin film 10, as shown in FIG. 1. This film is an acid transfer film in which the acid transfer composition of the present invention is used. Therefore, when the second resin film is exposed to a light, an acid generator (A) can generate an acid in the second resin film. The generated acid is selectively diffused into the first resin film, facing the exposure part of the second resin film and is uniformly diffused over the region. In addition, diffusion of unnecessary acids in the second resin film is prevented by the function of the polymer (B), whereby unnecessary acid transfer to the first resin film can be prevented.

The acid generated in the second resin film can be transferred to the first resin film by performing the later-described acid transfer process. The acid transferred to the first resin film causes an acid-dissociable group (protective group) in the acid-dissociable group-containing resin contained in the first resin film to dissociate, whereby the acid transfer part in the first resin film is made alkali soluble. As a result, a pattern consisting of an alkali soluble part and an alkali insoluble part can be formed in the first resin film. Subsequently, when the first resin film is developed using an alkaline developing solution or the like, as required, the alkali soluble portion can be removed to form a pattern which consists only of an alkali insoluble part.

The method for the formation of the second resin film is not particularly limited. The method for the application of the acid transfer composition is not particularly limited and example thereof includes a rotation application, a cast coating, a roll application, and the like.

After applying the acid transfer composition, the coating may optionally be prebaked (PB) to vaporize the solvent contained therein to form a second resin film (acid transfer film). The heating conditions for PB may be appropriately selected according to the acid transfer composition. The heating temperature is usually in the range from about 30° C. to 150° C., and preferably from 50° C. to 130° C. The heating time is usually in the range from 30 to 300 seconds, and preferably from 60 to 180 seconds.

The thickness of the second resin film formed on the first resin film is not particularly limited and is usually in the range from 1 to 10,000 nm, preferably from 5 to 800 nm, and more preferably from 10 to 500 nm.

### 3-2. Exposure Process (II)

The exposure process (II) is a process of exposing the second resin film to a light through a mask to generate an acid in the second resin film. The exposed area of the second resin film 20 is converted into an acid generation area 21 as shown in FIG. 1 by the exposure process (II).

The type of the radiation used for exposure is not particularly limited and it may be appropriately selected according to the type of the acid generator contained in the second resin film. Example thereof include ultraviolet rays, deep ultraviolet rays such as KrF excimer laser beams, ArF excimer laser beams and F₂ excimer laser beams, X-rays, electron beams, γ-rays, molecular beams, ion beams, and the like and these can be appropriately used. The exposure amount may also be appropriately selected according to the type of acid generator contained in the second resin film.

### 3-3. Acid Transfer Process (III)

The acid transfer process (III) is a process of transferring the acid generated in the second resin film to the first resin film. The part of the first resin film 10 corresponding to the acid generation area 21 becomes an acid transferred area 11 as shown in FIG. 1 by the acid transfer process (III).

There are no particular limitations to the method for transferring an acid. Examples of the method include (1) a method of transferring by heating, (2) a method of transferring by leaving at an ordinary temperature, (3) a method of transferring by using an osmotic pressure, and the like. These methods may be combined. Among these, the method of transferring by heating is preferable due to excellent transfer efficiency.

The conditions in the case of heating for transferring are not particularly limited. The heating temperature is preferably in the range from 50° C. to 200° C., and more preferably from 70° C. to 150° C., and the heating time is preferably in the range from 30 to 300 seconds, and more preferably from 60 to 180 seconds.

In addition, when transferring is performed by heating, the heating may be completed by one heating under the above-mentioned conditions, however, it is possible to heat twice or more times under the conditions if required to obtain the same results.

In the above-mentioned method (2) of transferring by leaving at an ordinary temperature, the acid generated in the second resin film spontaneously diffuses into the first resin film without heating, but by leaving the films in an environment of an ordinary temperature of usually 20° C. to 30° C.

In the above-mentioned method (3) of transferring by using an osmotic pressure, an osmotic pressure difference of the acid component is created between the first resin film and the second resin film by utilizing the acid concentration difference, whereby the acid in the second resin film can be made to diffuse into the first resin film at a rate higher than the spontaneous diffusion rate.

### 3-4. Second Resin Film Removing Process (IV)

The second resin film removing process (IV) is a process in which the second resin film is removed. That is to say, it is a process wherein the second resin film is removed to make the first resin film to which the acid is transferred to be exposed.

There are no particular limitations to the method for removing the second resin film. The second resin film is usually dissolved in an organic solvent for removal. The organic solvent is one capable of dissolving the second resin film, but not dissolving the first resin film to which the acid is transferred.

The organic solvent is appropriately selected according to the compositions of the first resin film and the second resin film and is not particularly limited so long as it is a solvent that dissolves the second resin film, but not dissolve the first resin film. Example thereof includes acetonitrile, acetone, tetrahydrofuran, pyridine and the like. These solvents may be used singly or in combination of two or more types thereof.

According to the pattern forming method of the present invention, a pattern consisting of a part to which an acid is transferred and a part to which no acid is transferred can be obtained by performing the above-mentioned second resin film formation process (I), exposure process (II), acid transfer process (III) and the second resin film removing process (IV) sequentially. Then, the development process (V) can be performed, as required. When the development process (V) is performed, a part 11 to which the acid is transferred which is obtained by the processes up to the process (TV) in FIG. 1, is removed from the first resin film 10 in FIG. 1, whereby a pattern consisting of the remaining part of the first resin film and the part from which the first resin film is removed can be obtained.

### 3-5. Development Process (V)

The development process (V) is a process of developing the first resin film using an alkaline developing solution after the second resin film removing process. That is to say, the development process (V) is a process wherein a pattern is obtained by removing an acid transferred part 11 which is formed in the first resin film 10, as shown in FIG. 1.

The alkaline developing solution is preferably used a solution prepared by dissolving at least one of an alkaline compound such as sodium hydroxide, potassium hydroxide, sodium carbonate, sodium silicate, sodium metasilicate, ammonia, ethyl amine, n-propyl amine, diethyl amine, di-n-propyl amine, triethyl amine, methyl diethyl amine, ethyl dimethyl amine, triethanol amine, tetramethyl ammonium hydroxide, pyrrole, piperidine, choline, 1,8-diazabicyclo-[5.4.0]-7-undecene and 1,5-diazabicyclo-[4.3.0]-5-nonane.

The concentration of the alkaline compound in the alkaline developing solution is not particularly limited and is preferably in the range from 0.1% to 5% by weight, and more preferably from 0.3% to 3% by weight.

The solvent in the alkaline developing solution is not particularly limited and example thereof includes water and an organic solvent. Examples of the organic solvent include a ketone such as acetone, methyl ethyl ketone, methyl sobutyl ketone, cyclopentanone, cyclohexanone, 3-methylcyclopentanone and 2,6-dimethylcyclohexanone; an alcohol such as methanol. ethanol, n-propanol, isopropanol, n-butanol, tert-butanol, cyclopentanol, cyclohexanol, 1,4-hexanediol and 1,4-hexanedimethylol, an ether such as tetrahydrofurane and dioxane, an ester such as ethyl acetate, n-butyl acetate and isoamyl acetate, an aromatic hydrocarbon such as toluene and xylene, phenol, acetonyl acetone, dimethylformamide and the like. The organic solvent may be used singly or in combination of two or more types thereof.

The alkaline developing solution may further contain an appropriate amount of a surfactant and the like.

In the pattern forming method of the present invention, other processes may be either provided or not provided in addition to the development process (V). Examples of the other processes include a washing process wherein the first resin film (which remains after removing the part to which the acid is transferred) is washed with water after the development process (V), and the like.

### EXAMPLES

Hereinafter, the embodiments of the present invention are described in detail using Examples. The present invention is in no way limited by these Examples. In addition, “part” and “%” in the description are based on weight unless otherwise indicated.

### 1. Preparation of First Resin Film Forming Composition

The following monomers were used for forming the acid-dissociable group-containing resin: bis-(4-methoxyphenyl)benzyl acrylate as a monomer having an acid-dissociable group, p-isopropenylphenol as a monomer having a phenolic hydroxyl group, and p-hydroxyphenylmethacrylamide, hydroxyethyl acrylate and phenoxypolyethylene glycol acrylate as other monomers.

20 g of bis-(4-methoxyphenyl)benzyl acrylate (9 mol % in 100 mol % of all monomers), 30 g of p-isopropenylphenol (37 mol % in 100 mol % of all monomers), 20 g of p-hydroxyphenylmethacrylamide (19 mol % in 100 mol % of all monomers), 20 g of hydroxyethyl acrylate (28 mol % in 100 mol % of all monomers), and 10 g of phenoxypolyethylene glycol acrylate (7 mol % in 100 mol % of all monomers) as a monomer, and 120 g of propylene glycol monomethyl ether acetate as a solvent were mixed to prepare a homogeneous solution. The resulting solution was bubbled with nitrogen gas for 30 minutes. Then, 4 g of 2,2′-azobis(isobutyronitrile) (AIBN) was added as a polymerization initiator to perform polymerization for three hours while bubbling nitrogen gas and maintaining a reaction temperature of 70° C. Next, 1 g of AIBN was further added to react for three hours. After that, the temperature was raised to 100° C. and reaction was continued for one hour before terminating the polymerization. The resulting reaction mixture was mixed with a large amount of hexane to coagulate the product in the reaction solution. Subsequently, the coagulate was redissolved in tetrahydrofuran, and the product was recoagulated by hexane. This operation was repeated several times to remove unreacted monomers. The resulting polymer was dried at a temperature of 50° C. under reduced pressure to obtain an acid-dissociable group-containing resin.

The yield of the resulting acid-dissociable group-containing resin was 95%, Mw was 15,000, and Mw/Mn was 2.5.

100 parts of the resulting acid-dissociable group-containing resin, 0.05 part of “NBX-15” (manufactured by Neos Co., Ltd.) as a surfactant, and 2,000 parts of propylene glycol monomethyl ether acetate as a solvent were mixed and stirred to obtain a homogeneous solution. This solution was filtered through a capsule filter with a pore diameter of 0.5 μm to obtain a first resin film forming composition.

The polymers in this example and later-described examples were analyzed by the following conditions.

Mw and Mn were measured by gel permeation chromatography (GPC) with monodispersed polystyrene as a standard reference material using a GPC column (manufactured by Tosoh Corp., G2000HXL×2, G3000HXL×1, G4000HXL×1) under the following analysis conditions. Flow rate: 1.0 ml/minute, eluate: tetrahydrofuran, column temperature: 40° C. The degree of dispersion (Mw/Mn) was calculated from the analysis results.

### 2. Preparation of Acid Transfer Composition

### 2-1. Polymer (B)

### Synthesis Example 1

### Polymer (B1)

This Synthesis Example 1 is one wherein N,N-dimethyl acrylamide represented by the following formula (19) and methyl methacrylate were respectively used as a monomer (Bm1) and a monomer (Bm2) to introduce a structural unit represented by the above formula (1) and a structural unit represented by the above formula (2) into a polymer.

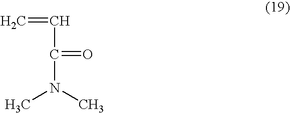

A 500 ml beaker was charged with 5 g of N,N-dimethylacrylamide manufactured by Kojin Co., Ltd., as a monomer (Bm1) (5 mol % in 100 mol % of the total of the monomer (Bm1) and monomer (Bm2)), 95 g of methyl methacrylate manufactured by Mitsubishi Materials Corp., as a monomer (Bm2) (95 mol % in 100 mol % of the total of the monomer (Bm1) and monomer (Bm2)), and 3.0 g of 2,2′-azobis(isobutyronitrile) as a polymerization initiator. The mixture was stirred until the initiator was dissolved to obtain a homogeneous monomer solution. On the other hand, 150 g of cyclohexanone as a solvent was charged into a separate flask which was equipped with a dry ice/methanol reflux condenser and was purged with a nitrogen gas, and was heated to a temperature of 80° C. while gently stirring.

Subsequently the above monomer solution was slowly added dropwise continuously into the cyclohexanone at 80° C. over two hours for polymerization. After the addition, the polymerization was continued for a further three hours at 80° C. The temperature was raised to 100° C. and then stirring was continued for an hour before terminating the polymerization. The resulting reaction mixture was added dropwise to a large amount of cyclohexane to coagulate the reaction product. The resulting coagulate was washed with water and dissolved in the same amount of tetrahydrofuran. The solution was added to a large amount of cyclohexane to recoagulate the product. This operation including redissolution and coagulation cycle was repeated three times. The resulting coagulate was dried at 40° C. under vacuum for 48 hours to obtain a polymer (B1).

The yield of the resulting polymer (B1) was 90%, Mw was 9,000, and Mw/Mn was 2.5 (see Table 1). The polymer (B1) was a resin having a structural unit represented by the above general formula (1).

### Synthesis Example 2

### Polymer (B2)

A polymer (B2) was obtained in the same manner as in Synthesis Example 1, except for using 10 g of N,N-dimethylacrylamide manufactured by Kojin Co., Ltd. (10 mol % in 100 mmol % of the total of the monomer (Bm1) and monomer (Bm2)) as a monomer (Bm1), 90 g of methyl methacrylate manufactured by Mitsubishi Materials Corp. (90 mol % in 100 mol % of the total of the monomer (Bm1) and monomer (Bm2)) as a monomer (Bm2).

Mw of the resulting polymer (B2) was 10,000 (see Table 1). The polymer (B2) was a resin having the structural unit represented by the above general formula (1).

### Synthesis Example 3

### Polymer (B3)

A polymer (B3) was obtained in the same manner as in Synthesis Example 1, except for using 20 g of N,N-dimethylacrylamide manufactured by Kojin Co., Ltd. (20 mol % in 100 mol % of the total of the monomer (Bm1) and monomer (Bm2)) as a monomer (Bm1), 80 g of methyl methacrylate manufactured by Mitsubishi Materials Corp. (80 mol % in 100 mol % of the total of the monomer (Bm1) and monomer (B 2)) as a monomer (Bm2).

Mw of the resulting polymer (B3) was 9,000 (see Table 1). The polymer (B3) was a resin having a structural unit represented by the above general formula (1).

TABLE 1

| | Monomer (mol %) | | |
|---|---|---|---|
| | N,N- | Methyl | Weight average |
| Polymer B | dimethylacrylamide | methacrylate | molecular weight |
| B1 | 5 | 95 | 9,000 |
| B2 | 10 | 90 | 10,000 |
| B3 | 20 | 80 | 9,000 |

### 2-2. Other Components

### (1) Acid Generator (A)

Acid generators (A1) to (A3) represented by the following formulae (5) to (7) were used.

Acid generator (A1) is a product “NAI-100” manufactured by Midori Kagaku Co., Ltd.

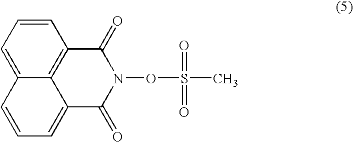

Acid generator (A2) is a product “NAI-101” manufactured by Midori Kagaku Co., Ltd.

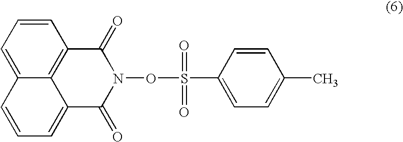

Acid generator (A3) is a product “NAI-106” manufactured by Midori Kagaku Co., Ltd.

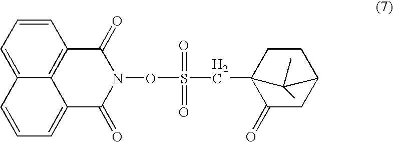

### (2) Solvent (C)

Cyclohexanone (C1) was used. γ-Butyrolactone (C2) and propylene glycol monomethyl ether acetate (C3) were used as other solvents (C′).

### (3) Additives

“Dinaflow” (manufactured by JSR, Inc.) was used as a surfactant (D).

2-isopropylthioxanthone (“SPEEDCURE TTX” manufactured by Lambson Ltd.) represented by the following formula (20-1) was used as a sensitizer (E).

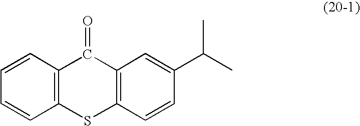

### 2-3. Preparation of Acid Transfer Composition

The above raw materials, that is, 100 to 200 parts of the acid generators (A1) to (A3), 100 parts of the polymers (B1) to (B3), 1,600 to 1,800 parts of the solvent, 0.05 part of the surfactant, and 43 parts of the sensitizer were mixed in proportions shown in Table 2. The mixture was stirred to produce a homogeneous solution. The solutions were filtered through a capsule filter with a pore diameter of 0.5 μm to obtain 18 acid transfer compositions (Examples 1 to 11 and Comparative Examples 1 to 7).

TABLE 2

| | Acid | | | | | | | |
|---|---|---|---|---|---|---|---|---|
| | generator | | Polymer | | | | | |
| | (A) | | (B) | | Solvent (C) | | Surfactant (D) | Sensitizer (E) |
| | Type | Part | Type | Part | Type | Part | Part | Part |
| Example 1 | A1 | 100 | B3 | 100 | C1 | 1,800 | 0.05 | — |
| Example 2 | A1 | 200 | B3 | 100 | C1 | 1,700 | 0.05 | — |
| Example 3 | A2 | 100 | B3 | 100 | C1 | 1,800 | 0.05 | — |
| Example 4 | A2 | 200 | B3 | 100 | C1 | 1,700 | 0.05 | — |
| Example 5 | A3 | 100 | B1 | 100 | C1 | 1,800 | 0.05 | — |
| Example 6 | A3 | 100 | B2 | 100 | C1 | 1,800 | 0.05 | — |
| Example 7 | A3 | 100 | B3 | 100 | C1 | 1,800 | 0.05 | — |
| Example 8 | A3 | 200 | B3 | 100 | C1/C3 | 1,500/200 | 0.05 | — |
| Example 9 | A3 | 200 | B3 | 100 | C1/C3 | 1,500/100 | 0.05 | — |
| Example 10 | A3 | 200 | B3 | 100 | C1/C2 | 1,500/100 | 0.05 | — |
| Example 11 | A3 | 43 | B3 | 100 | C1 | 1,800 | 0.05 | 43 |
| Comparative Example 1 | A1 | 100 | B3 | 100 | C2 | 1,800 | 0.05 | — |
| Comparative Example 2 | A2 | 100 | B3 | 100 | C2 | 1,800 | 0.05 | — |
| Comparative Example 3 | A3 | 100 | B3 | 100 | C2 | 1,800 | 0.05 | — |
| Comparative Example 4 | A3 | 200 | B3 | 100 | C2 | 1,700 | 0.05 | — |
| Comparative Example 5 | A3 | 200 | B3 | 100 | C2/C3 | 1,400/300 | 0.05 | — |
| Comparative Example 6 | A3 | 200 | B3 | 100 | C2/C3 | 300/1,400 | 0.05 | — |
| Comparative Example 7 | A3 | 100 | B1 | 100 | C2 | 1,800 | 0.05 | — |

### 3. Pattern Formation

### (1) First Resin Film Formation Process

The first resin film forming composition obtained above was applied to the surface of a 4-inch silicon wafer using a spin coater, followed by heating on a hot plate at 110° C. for one minute to form a first resin film having a thickness of 200 nm.

### (2) Acid Transfer Film Formation Process (I)

Each of the acid transfer compositions of Examples 1 to 10 and Comparative Examples 1 to 7 was applied to the surface of the first resin film obtained in (1) above using a spin coater, followed by heating on a hot plate at 110° C. for one minute to form an acid transfer film having a thickness of 150 nm.

### (3) Exposure Process (II)

The surface of the acid transfer film obtained in (2) above was exposed to ultraviolet rays at an intensity of 100 to 1,000 mJ/cm² using an ultrahigh pressure mercury lamp (“HBO” manufactured by OSRAM, output 1,000 W) through a pattern mask. The amount of exposure was confirmed using an instrument in which an illuminometer “UV-M10” (manufactured by ORC Manufacturing Co., Ltd.) was connected to a photoreceiver “Probe UV-35” (manufactured by ORC Manufacturing Co., Ltd.).

### (4) Acid Transfer Process (III)

The laminate obtained in the processes up to (3) above was heated on a hot plate at a temperature of 110° C. for one minute.

### (5) Acid Transfer Film Removing Process (IV)

The laminate obtained in the processes up to (4) above was dipped in acetonitrile for 30 seconds to remove only the acid transfer film.

### (6) Development Process (V)

The laminate obtained in the processes up to (5) above was dipped in a 2.38% tetramethylammonium hydroxide aqueous solution at room temperature for one minute for development, followed by washing in flowing water and blowing using nitrogen gas to form a pattern.

The substrate on which a pattern was formed in this manner is hereinafter called “a patterned substrate”.

### 4. Solubility Evaluation

The compositions for Examples 1 to 11 and Comparative Examples 1 to 7 (solutions obtained by mixing and stirring raw materials shown in Table 2 before filtration) were observed to evaluate solubility. The solubility was evaluated by the transparency of the composition which was allowed to stand for one hour or more after mixing and stirring (before filtration). A composition having no undissolved residue was evaluated as “Good”, and a composition having an undissolved residue which was not transparent was evaluated as “Bad”. The results are shown in Table 3.

### 5. Sensitivity Evaluation

The sensitivity was evaluated by observing the patterned substrate by an optical microscope. The sensitivity indicates a minimum exposure amount capable of resolving a 50/50 μm line/space pattern without a residue and this exposure amount was taken as an “optimum dose”. The results are shown in Table 3.

### 6. Dimensional Evaluation

A patterned substrate processed by the optimum dose was observed using a scanning electron microscope to measure the 50/50 μm line/space pattern. When the gap of the measured dimension from the mask dimension was 0 μm or more and less than 5 μm, the dimensional evaluation was rated as “Good”, and when it was 5 μm or more, it was rated as “Bad”. The results are shown in Table 3.

### 7. In-Plane Dimensional Uniformity Evaluation

A patterned substrate processed by the optimum dose was observed using a scanning electron microscope to measure the dimensions of 200 50/50 μm line/space patterns. The gap of the measured dimension from the mask dimension was measured. The number of patterns at which the gap was 0 μm or more and less than 5 μm (patterns which acquired “Good” results in the above dimensional evaluation) and the number of patterns at which the gap was 5 μm or more (patterns acquired “Bad” results in the above dimensional evaluation) were counted to determine the percentage (%) of patterns in which the gap was 0 μm or more and less than 5 μm in all patterns formed on the entire surface of the substrate. The in-plane dimensional uniformity was rated as “Good” when the percentage of patterns with a gap of 0 μm or more and less than 5 μm was 70% or more, and as “Bad” when it was less than 70%.

TABLE 3

| | | | | In-plane dimen- |
|---|---|---|---|---|
| | | Sensitivity | Dimensional | sional uniformity |
| | Solubility | (mJ · cm⁻²) | evaluation | evaluation (%) |
| Example 1 | Good | 800 | Good | Good (75%) |
| Example 2 | Good | 400 | Good | Good (70%) |
| Example 3 | Good | 800 | Good | Good (85%) |
| Example 4 | Good | 400 | Good | Good (80%) |
| Example 5 | Good | 600 | Good | Good (85%) |
| Example 6 | Good | 700 | Good | Good (85%) |
| Example 7 | Good | 800 | Good | Good (80%) |
| Example 8 | Good | 400 | Good | Good (70%) |
| Example 9 | Good | 400 | Good | Good (70%) |
| Example 10 | Good | 500 | Good | Good (70%) |
| Example 11 | Good | 300 | Good | Good (80%) |
| Comparative | Good | 600 | Good | Bad (60%) |
| Example 1 | | | | |
| Comparative | Good | 700 | Good | Bad (65%) |
| Example 2 | | | | |
| Comparative | Good | 800 | Good | Bad (65%) |
| Example 3 | | | | |
| Comparative | Good | 400 | Good | Bad (60%) |
| Example 4 | | | | |
| Comparative | Good | 400 | Good | Bad (60%) |
| Example 5 | | | | |
| Comparative | Bad | — | — | — |
| Example 6 | | | | |
| Comparative | Good | 700 | Good | Bad (65%) |
| Example 7 | | | | |

What is claimed is:

1. An acid transfer composition comprising (A) a radiation-sensitive acid generator, (B) a polymer having a nitrogen-containing group, and (C) a ketone-based solvent.

2. The acid transfer composition according to claim 1, wherein said polymer (B) comprises a polymer having a structural unit represented by the following general formula (1), 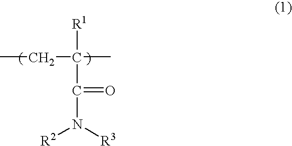
wherein R¹ is a hydrogen atom or a methyl group, and R² and R³ individually are a hydrogen atom, a linear or branched hydrocarbon group having 1 to 10 carbon atoms, or a cyclic hydrocarbon group having 3 to 10 carbon atoms, or R² and R³ may bond to form a 3 to 10 membered monocyclic hetero ring containing a nitrogen atom, an oxygen atom, a sulfur atom or a selenium atom.

3. The acid transfer composition according to claim 1, wherein said ketone-based solvent is contained in an amount from 10 to 10,000 parts by weight based on 100 parts by weight of said polymer (B).

4. The acid transfer composition according to claim 1, wherein said polymer (B) has a structural unit represented by the following general formula (2), 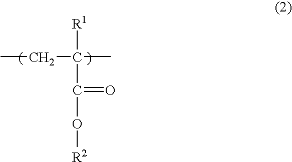
wherein R¹ is a hydrogen atom or a methyl group, and R² is a monovalent organic group.

5. The acid transfer composition according to claim 1, wherein said radiation-sensitive acid generator (A) is a compound having an imide sulfonate group.

6. The acid transfer composition according to claim 1, further comprising (E) a sensitizer.

7. The acid transfer composition according to claim 6, wherein said sensitizer (B) is a compound represented by the following general formula (20), 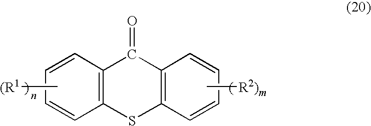
wherein R¹ and R² individually are an alkyl group or a halogen atom, and n and m individually an integer of 1 to 4.

8. An acid transfer film which is formed using said acid transfer composition according to claim 1.

9. The acid transfer film according to claim 8, wherein said polymer (B) comprises a polymer having a structural unit represented by the following general formula (1), 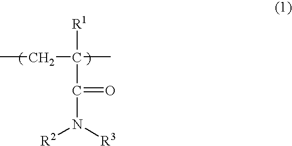
wherein R¹ is a hydrogen atom or a methyl group, and R² and R³ individually are a hydrogen atom, a linear or branched hydrocarbon group having 1 to 10 carbon atoms, or a cyclic hydrocarbon group having 3 to 10 carbon atoms, or R² and R³ may bond to form a 3 to 10 membered monocyclic hetero ring containing a nitrogen atom, an oxygen atom, a sulfur atom or a selenium atom.

10. The acid transfer film according to claim 8, wherein said ketone-based solvent is contained in an amount from 10 to 10,000 parts by weight based on 100 parts by weight of said polymer (B).

11. The acid transfer film according to claim 8, wherein said polymer (B) has a structural unit represented by the following general formula (2), 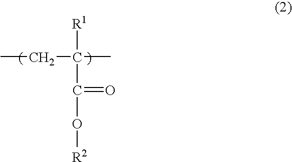
wherein R¹ is a hydrogen atom or a methyl group, and R² is a monovalent organic group.

12. The acid transfer film according to claim 8, wherein said radiation-sensitive acid generator (A) is a compound having an imide sulfonate group.

13. The acid transfer film according to claim 8, wherein said acid transfer composition comprises (E) a sensitizer.

14. The acid transfer film according to claim 13, said sensitizer (E) is a compound represented by the following general formula (20), 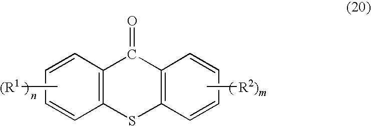
wherein R¹ and R² individually are an alkyl group or a halogen atom, and n and m individually an integer of 1 to 4.

15. A pattern forming method comprising sequentially,
(I) a second resin film formation process for forming a second resin film as an acid transfer film on a first resin film using said acid transfer composition according to claim 1, said first resin film comprising an acid-dissociable group-containing resin, but not comprising a radiation-sensitive acid generator,
(II) an exposure process for exposing said second resin film to a light through a mask to generate an acid in said second resin film,
(III) an acid transfer process for transferring said acid generated in said second resin film to said first resin film, and
(IV) a second resin film removing process for removing said second resin film.
